(19) United States
(12) Patent Application Publication
(10) Pub. No.: US 2024/0379737 A1
(43) Pub. Date: Nov. 14, 2024

(54) CAPACITOR DEVICE AND SEMICONDUCTOR DEVICE

(71) Applicant: ROHM CO., LTD., Kyoto-shi (JP)

(72) Inventors: Ryosuke ISHIDO, Kyoto-shi (JP); Yuta OKAWAUCHI, Kyoto-shi (JP)

(21) Appl. No.: 18/779,831

(22) Filed: Jul. 22, 2024

Related U.S. Application Data
(63) Continuation of application No. PCT/JP2023/000556, filed on Jan. 12, 2023.

(30) Foreign Application Priority Data
Jan. 27, 2022 (JP) 2022-011036

(51) Int. Cl. H01G 4/012; H01G 4/232; H01L 23/31; H01L 23/373; H01L 25/07; H01L 25/16

(52) U.S. Cl. CPC H01L 28/90; H01G 4/012; H01G 4/232; H01L 23/3121; H01L 23/3735; H01L 25/072; H01L 25/16

(57) ABSTRACT

A capacitor device includes a capacitor element, an insulating cover covering the capacitor element, a first external electrode exposed from the insulating cover, a second external electrode exposed from the insulating cover, a first conductive member electrically conducting to the first external electrode and the capacitor element, and a second conductive member electrically conducting to the second external electrode and the capacitor element. The capacitor element includes a multilayer body comprising a plurality of dielectric layers and a plurality of conductor layers alternately laminated in a first direction. The insulating cover covers the entirety of the capacitor element except a connection portion where the capacitor element and the first conductive member are connected and a connection portion where the capacitor element and the second conductive member are connected. The first external electrode and the second external electrode are formed on opposite sides of each other in the first direction.

### TECHNICAL FIELD

The present disclosure relates to a capacitor device and a semiconductor device.

### BACKGROUND ART

Conventionally, capacitors are used in the electronic circuits of power conversion devices (inverters, etc.) built in vehicles, industrial machinery, etc., in order to smooth voltage, for example. A chip-type multilayer capacitor is disclosed in JP-A-2018-104210. The multilayer capacitor described in JP-A-2018-104210 includes a multilayer body and a first and a second external electrodes. The multilayer body has a plurality of dielectric ceramic layers and a plurality of first and second internal electrodes. The dielectric ceramic layers and the first and the second internal electrodes are alternately laminated. In the lamination direction of the dielectric ceramic layers and the first and the second internal electrodes, each of the first and the second internal electrodes is located between dielectric ceramic layers. The first external electrode and the second external electrode are electrically connected to the first internal electrodes and the second internal electrodes, respectively. The first external electrode and the second external electrode are formed at opposite ends of the multilayer body in a orthogonal direction that is orthogonal to the lamination direction.

As described in, for example, WO-A1-2019/216161, a chip-type multilayer capacitor may be incorporated in a semiconductor module. In WO-A1-2019/216161, the chip capacitor is mounted to two conductors spaced apart in the orthogonal direction.

### BRIEF DESCRIPTION OF THE DRAWINGS

FIG. 1 is a perspective view showing a capacitor device according to a first embodiment.

FIG. 2 is a plan view showing the capacitor device according to the first embodiment.

FIG. 3 is a bottom view showing the capacitor device according to the first embodiment.

FIG. 4 is a sectional view taken along line IV-IV in FIG. 2.

FIG. 5 is a plan view showing a first electrode layer of the capacitor device according to the first embodiment.

FIG. 6 is a plan view showing a dielectric layer of the capacitor device according to the first embodiment.

FIG. 7 is a plan view showing a second electrode layer of the capacitor device according to the first embodiment.

FIG. 8 is a plan view showing a capacitor device according to a second embodiment.

FIG. 9 is a sectional view taken along line IX-IX in FIG. 8.

FIG. 10 is a sectional view corresponding to FIG. 4 and showing a capacitor device according to a third embodiment.

FIG. 11 is a plan view showing a capacitor device according to a fourth embodiment.

FIG. 12 is a plan view showing a capacitor device according to a fifth embodiment.

FIG. 13 is a sectional view taken along line XIII-XIII in FIG. 12.

FIG. 14 is a plan view showing a capacitor device according to a sixth embodiment.

FIG. 15 is a bottom view showing a capacitor device according to a sixth embodiment.

FIG. 16 is a sectional view taken along line XVI-XVI in FIG. 14.

FIG. 17 is a plan view showing a capacitor device according to a seventh embodiment.

FIG. 18 is a bottom view showing the capacitor device according to the seventh embodiment.

FIG. 19 is a sectional view taken along line XIX-XIX in FIG. 17.

FIG. 20 is a plan view showing a capacitor device according to an eighth embodiment.

FIG. 21 is a sectional view taken along line XXI-XXI in FIG. 20.

FIG. 22 is a plan view showing a capacitor device according to a ninth embodiment.

FIG. 23 is a sectional view taken along line XXIII-XXIII in FIG. 22.

FIG. 24 is a plan view showing a capacitor device according to a variation.

FIG. 25 is a plan view showing the first electrode layer of a capacitor device according to a variation.

FIG. 26 is a perspective view showing a semiconductor device according to a first embodiment.

FIG. 27 is a perspective view corresponding to FIG. 26, from which the resin member is omitted.

FIG. 28 is a plan view showing a semiconductor device according to a first embodiment.

FIG. 29 is a plan view corresponding to FIG. 28, in which the resin member is shown by imaginary lines.

FIG. 30 is a plan view corresponding to FIG. 29, in which two input terminals and the output terminal are shown by imaginary lines.

FIG. 31 is a partial enlarged view in which a part of FIG. 30 is enlarged.

FIG. 32 is a front view showing the semiconductor device according to the first embodiment.

FIG. 33 is a bottom view showing the semiconductor device according to the first embodiment.

FIG. 34 is a side view (left side view) showing the semiconductor device according to the first embodiment.

FIG. 35 is a sectional view taken along line XXXV-XXXV in FIG. 29.

FIG. 36 is a schematic partial enlarged view in which a part of FIG. 35 is enlarged and a connecting member (gate wire) is omitted.

FIG. 37 is a plan view showing a semiconductor device according to a second embodiment, in which two input terminals and the output terminal are shown by imaginary lines.

FIG. 38 is a sectional view corresponding to FIG. 35 and showing the semiconductor device according to the second embodiment.

FIG. 39 is a plan view showing a semiconductor device according to a third embodiment, in which the resin member is shown by imaginary lines.

FIG. 40 is a plan view corresponding to FIG. 39, in which two input terminals and the output terminal are shown by imaginary lines.

FIG. 41 is a sectional view taken along line XLI-XLI in FIG. 40.

FIG. 42 is a plan view showing a capacitor device included in the semiconductor device according to the third embodiment.

FIG. 43 is a sectional view taken along line XLIII-XLIII in FIG. 42.

FIG. 44 is a plan view showing a semiconductor device according to a fourth embodiment, in which the resin member, two input terminals and the output terminal are shown by imaginary lines.

FIG. 45 is a plan view showing a capacitor device included in the semiconductor device according to the fourth embodiment.

FIG. 46 is a plan view showing a semiconductor device according to a fifth embodiment.

FIG. 47 is a plan view corresponding to FIG. 46, in which the resin member is shown by imaginary lines.

FIG. 48 is a plan view corresponding to FIG. 47, in which the output terminal and the conductive member are shown by imaginary lines.

FIG. 49 is a sectional view taken along line XLIX-XLIX in FIG. 47.

FIG. 50 is a sectional view taken along line L-L in FIG. 47.

FIG. 51 is a partial enlarged view in which a part of FIG. 50 is enlarged.

FIG. 52 is a plan view showing a semiconductor device according to a sixth embodiment, in which the resin member is shown by imaginary lines.

FIG. 53 is a sectional view taken along line LIII-LIII in FIG. 52.

FIG. 54 is a partial enlarged view in which a part of FIG. 53 is enlarged.

### DETAILED DESCRIPTION OF EMBODIMENTS

Preferred embodiments of a capacitor device and a semiconductor device according to the present disclosure are described below with reference to the accompanying drawings. Hereinafter, the same or similar elements are denoted by the same reference signs, and the descriptions thereof are omitted. In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”.

### Capacitor Device:

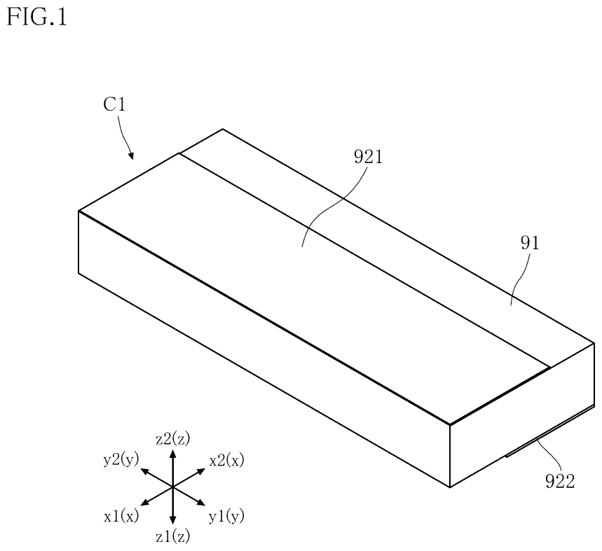

FIGS. 1 to 7 show a capacitor device according to a first embodiment. As shown in these figures, the capacitor device C1 of the first embodiment includes a capacitor element 8, an insulating cover 91, a first external electrode 921, a second external electrode 922, a first conductive member 931, and a second conductive member 932.

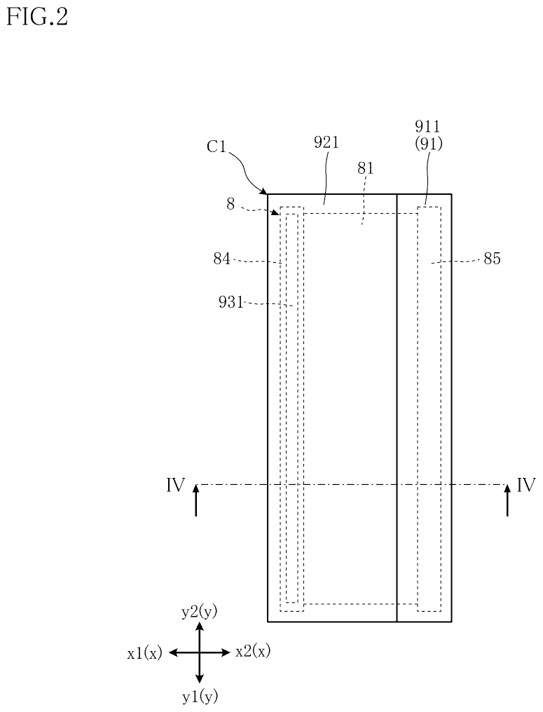

For the convenience of description, the thickness direction of the capacitor device C1 is defined as the “first direction z”. Herein, the terms such as “top”, “bottom”, “upper”, “lower”, “upper surface”, and “lower surface” are used to indicate the relative positional relationship of parts, portions or the like in the first direction z and do not necessarily define the relationship with respect to the direction of gravity. Also, “plan view” refers to the view seen in the first direction z. A direction orthogonal to the first direction z is defined as the “second direction x”, and the direction orthogonal to the first direction z and the second direction x is defined as the “third direction y”. As an example, the second direction x is the horizontal direction in plan view (see FIG. 2) of the capacitor device C1, and the third direction y is the vertical direction in plan view (see FIG. 2) of the capacitor device C1.

As shown in FIG. 1, the capacitor device C1 has the shape of a rectangular parallelepiped, for example. In the example shown in FIG. 2, the capacitor device C1 has a rectangular shape elongated in the third direction y in plan view, but unlike this example, the capacitor device may have a rectangular shape elongated in the second direction x. Alternatively, the capacitor device C1 may have a square shape in plan view.

The capacitor element 8 is, for example, a chip-type multilayer capacitor, such as a film capacitor or a ceramic capacitor. The capacitor element 8 may be other capacitors, not a multilayer capacitor. The capacitor element 8 may have a self-healing function. The capacitor element 8 includes a multilayer body 81, a first aggregate electrode 84, and a second aggregate electrode 85.

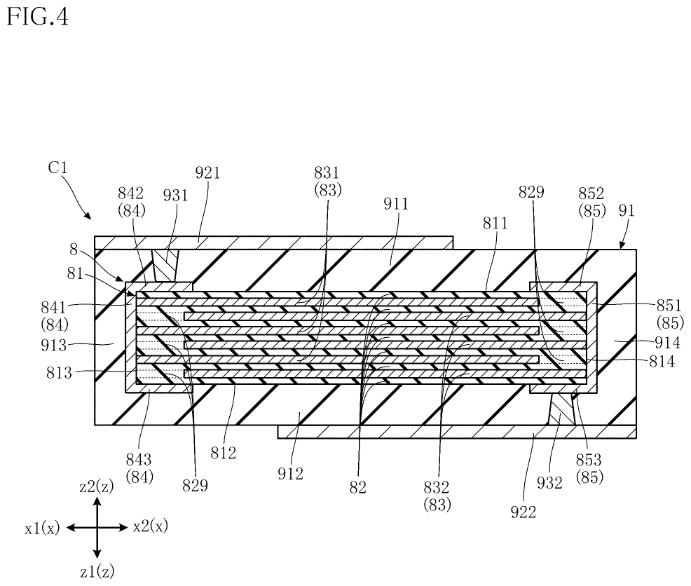

The multilayer body 81 is the core component for the function of the capacitor element 8. As shown in FIGS. 4 to 7, the multilayer body 81 has an obverse surface 811, a reverse surface 812, a first side surface 813, a second side surface 814, a third side surface 815, and a fourth side surface 816. As shown in FIGS. 4 to 7, the multilayer body 81 includes a plurality of dielectric layers 82 and a plurality of conductor layers 83.

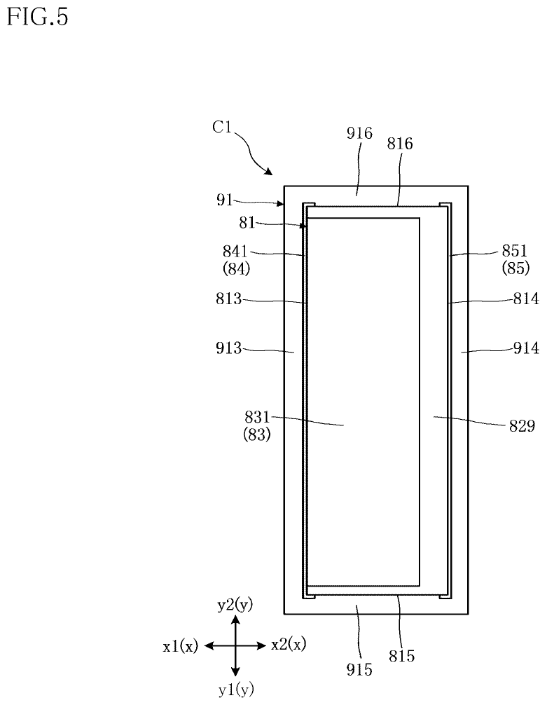

As shown in FIG. 4, the obverse surface 811 and the reverse surface 812 are spaced apart in the first direction z. The obverse surface 811 faces the z2 side in the first direction, and the reverse surface 812 faces the z1 side in the first direction. As shown in FIGS. 5 to 7, the first side surface 813 and the second side surface 814 are spaced apart in the second direction x. The first side surface 813 faces the x1 side in the second direction, and the second side surface 814 faces the x2 side in the second direction. As shown in FIGS. 5 to 7, the third side surface 813 and the fourth side surface 816 are spaced apart in the third direction y. The third side surface 815 faces the y1 side in the third direction, and the fourth side surface 816 faces the y2 side in the third direction. The obverse surface 811, the reverse surface 812, the first side surface 813, the second side surface 814, the third side surface 815, and the fourth side surface 816 are flat, for example.

As shown in FIG. 4, the dielectric layers 82 and the conductor layers 83 are alternately laminated in the first direction z in the multilayer body 81. In the present disclosure, the lamination direction of the multilayer body 81 corresponds to the first direction z. The number of lamination (the number of dielectric layers 82 and the number of conductor layers 83) is not limited to the example shown in FIG. 4 and can be changed as appropriate depending on the specifications (e.g., capacitance) of the capacitor device C1.

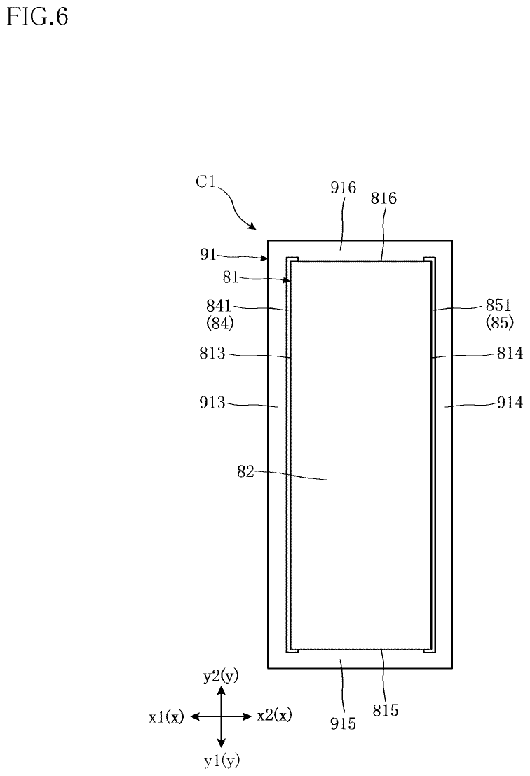

Each of the dielectric layers 82 is sandwiched between adjacent conductor layers 83 in the first direction z. As shown in FIG. 4, the dielectric layer 82 located outermost on each side in the first direction z forms the surface layer of the multilayer body 81 on each side in first direction z. As shown in FIG. 6, the dielectric layers 82 are in contact with the first side surface 813, the second side surface 814, the third side surface 815, and the fourth side surface 816 in plan view. In the example where the capacitor element 8 is a film capacitor, each of the dielectric layers 82 is made of an insulating resin material, for example. In the example where the capacitor element 8 is a ceramic capacitor, each of the dielectric layers 82 is made of ceramic, for example. The constituent material of the dielectric layers 82 is not limited to the above examples and may be other insulating materials.

The conductor layers 83 are made of copper or a copper alloy, for example. The constituent material of the conductor layers 83 is not limited to copper or a copper alloy. As shown in FIG. 4, each of the conductor layers 83 is disposed between dielectric layers 82.

As shown in FIGS. 4, 5 and 7, the plurality of conductor layers 83 include a plurality of first electrode layers 831 and a plurality of second electrode layers 832. The first electrode layers 831 and the second electrode layers 832 are alternately disposed in the first direction z. Each first electrode layer 831 and a relevant second electrode layer 832 sandwich a dielectric layer 82 in the first direction z. When the capacitor device C1 is energized, the first electrode layers 831 and the second electrode layers 832 have mutually opposite polarities.

As shown in FIGS. 4 and 5, the first electrode layers 831 are connected to the first aggregate electrode 84. The first electrode layers 831 are at the same potential via the first aggregate electrode 84. As shown in FIG. 5, the first electrode layers 831 are in contact with the first side surface 813 and spaced apart from the second side surface 814, the third side surface 815 and the fourth side surface 816 in plan view. The first electrode layers 831 are spaced apart from the second aggregate electrode 85 in the second direction x. As shown in FIGS. 4 and 5, an insulator 829 is disposed around each first electrode layer 831 (excluding the edge in contact with the first aggregate electrode 84) in plan view. In one example, the insulator 829 is made of the same material as the dielectric layers 82.

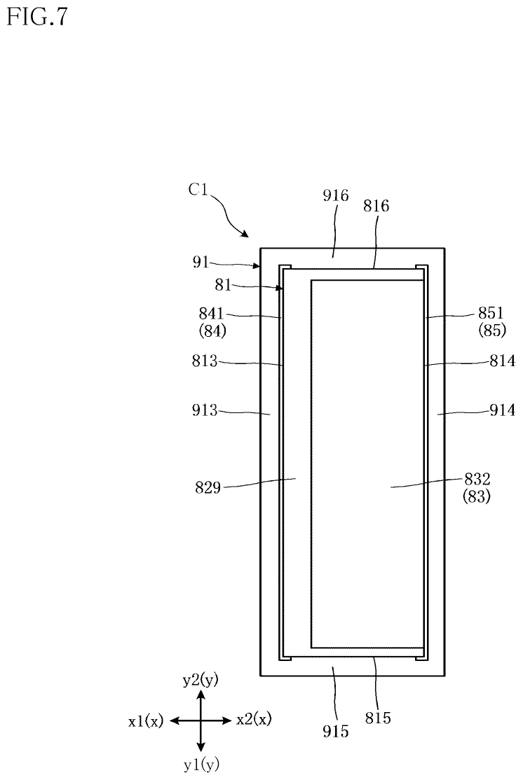

As shown in FIGS. 4 and 7, the second electrode layers 832 are connected to the second aggregate electrode 85. The second electrode 832 are at the same potential via the second aggregate electrode 85. As shown in FIG. 7, the second electrode layers 832 are in contact with the second side surface 814 and spaced apart from the first side surface 813, the third side surface 815 and the fourth side surface 816 in plan view. The second electrode layers 832 are spaced apart from the first aggregate electrode 84 in the second direction x. As shown in FIGS. 4 and 7, an insulator 829 is disposed around each second electrode layer 832 (excluding the edge in contact with the second aggregate electrode 85) in plan view.

The first aggregate electrode 84 electrically conducts to the first electrode layers 831 and electrically connects the first electrode layers 831 to each other. The first aggregate electrode 84 is formed to cover the end on the x1 side in the second direction of the multilayer body 81. As shown in FIG. 4, the first aggregate electrode 84 includes a first side electrode portion 841, a first obverse electrode portion 842, and a first reverse electrode portion 843.

As shown in FIG. 4, the first side electrode portion 841 covers the first side surface 813. In the present embodiment, the first side electrode portion 841 covers the entirety of the first side surface 813. The first side electrode portion 841 is in contact with the first electrode layers 831.

As shown in FIG. 4, the first obverse electrode portion 842 covers a part of the obverse surface 811. The first obverse electrode portion 842 is connected to the first side electrode portion 841 and formed on an end of the obverse surface 811 that is connected to the first side surface 813.

As shown in FIG. 4, the first reverse electrode portion 843 covers a part of the reverse surface 812. The first reverse electrode portion 843 is connected to the first side electrode portion 841 and formed on an end of the reverse surface 812 that is connected to the first side surface 813.

As shown in FIGS. 5 to 7, the first aggregate electrode 84 includes a portion covering a part of the third side surface 815 and a portion covering a part of the fourth side surface 816 in addition to the first side electrode portion 841, the first obverse electrode portion 842 and the first reverse electrode portion 843.

The second aggregate electrode 85 electrically conducts to the second electrode layers 832 and electrically connects the second electrode layers 832 to each other. The second aggregate electrode 85 is formed to cover the end on the x2 side in the second direction of the multilayer body 81. As shown in FIG. 4, the second aggregate electrode 85 includes a second side electrode portion 851, a second obverse electrode portion 852, and a second reverse electrode portion 853.

As shown in FIG. 4, the second side electrode portion 851 covers the second side surface 814. In the present embodiment, the second side electrode portion 851 covers the entirety of the second side surface 814. The second side electrode portion 851 is in contact with the second electrode layers 832.

As shown in FIG. 4, the second obverse electrode portion 852 covers a portion of the obverse surface 811. The second obverse electrode portion 852 is connected to the second side electrode portion 851 and formed on an end of the obverse surface 811 that is connected to the second side surface 814.

As shown in FIG. 4, the second reverse electrode portion 853 covers a part of the reverse surface 812. The second reverse electrode portion 853 is connected to the second side electrode portion 851 and formed on an end of the reverse surface 812 that is connected to the second side surface 814.

As shown in FIGS. 5 to 7, the second aggregate electrode 85 includes a portion covering a part of the third side surface 815 and a portion covering a part of the fourth side surface 816 in addition to the second side electrode portion 851, the second obverse electrode portion 852 and the second reverse electrode portion 853.

As shown in FIGS. 2 to 4, the insulating cover 91 covers the entirety of the capacitor element 8 except a connection portion where the capacitor element 8 and the first conductive member 931 are connected and a connection portion where the capacitor element 8 and the second conductive member 932 are connected. In the capacitor device C1, the constituent material of the insulating cover 91 differs from the constituent material of the dielectric layers 82, and is, for example, a polymer compound. The polymer compound may be, for example, a prepreg made of epoxy resin, glass fiber, phenolic resin, rubber, etc. Unlike this arrangement, the constituent material of the insulating cover 91 may be the same as that of the dielectric layers 82. However, using different materials for the insulating cover 91 and the dielectric layers 82 allows selecting the material for the insulating cover 91 and the material for the dielectric layers 82 depending on respective purposes. For example, a material with high dielectric strength or thermal conductivity may be used for the insulating cover 91, while a material with high dielectric constant may be used for the dielectric layers 82.

As shown in FIGS. 2 to 7, the insulating cover 91 includes an obverse covering portion 911, a reverse covering portion 912, a first side covering portion 913, a second side covering portion 914, a third side covering portion 915, and a fourth side covering portion 916. As shown in FIG. 4, the obverse covering portion 911 covers the obverse surface 811. The obverse covering portion 911 also covers a part of the first conductive member 931. As shown in FIG. 4, the reverse covering portion 912 covers the reverse surface 812. The reverse covering portion 912 also covers a part of the second conductive member 932. The first side covering portion 913 covers the first side surface 813. The second side covering portion 914 covers the second side surface 814. The third side covering portion 915 covers the third side surface 815.

The fourth side covering portion 916 covers the fourth side surface 816.

As shown in FIG. 4, the first external electrode 921 and the second external electrode 922 are formed on opposite sides of each other in the first direction z (the lamination direction of the multilayer body 81). The first external electrode 921 and the second external electrode 922 are disposed with the capacitor element 8 therebetween in the first direction z. The first external electrode 921 and the second external electrode 922 are the terminals of the capacitor device C1. As understood from FIG. 4, a part of the first external electrode 921 and a part of the second external electrode 922 overlap with each other in plan view in the present embodiment. The first external electrode 921 and the second external electrode 922 are made of, for example, copper or a copper alloy. The first external electrode 921 and the second external electrode 922 may not be made of copper or a copper alloy, and may be made of gold, silver, Ni (nickel), aluminum, tin, alloys of these, or conductive resin.

The first external electrode 921 covers at least a part of the obverse covering portion 911. In the example shown in FIGS. 2 and 4, a part of the obverse covering portion 911 is exposed from the first external electrode 921. In the example shown in FIGS. 2 and 4, the first external electrode 921 is formed on the end of the obverse covering portion 911 that is connected to the first side covering portion 913, and the end of the obverse covering portion 911 that is connected to the second side covering portion 914 is exposed. In the example shown in FIGS. 2 and 4, the area of the obverse covering portion 911 that is covered with the first external electrode 921 is larger than the area that is exposed from the first external electrode 921, but the opposite may be the case. Unlike this example, the first external electrode 921 may cover the entire upper surface of the obverse covering portion 911. A larger area in plan view of the first external electrode 921 leads to an increased bonding area to a mounting target and improved heat dissipation to the mounting target. In the example shown in FIG. 2, the first external electrode 921 is rectangular in plan view.

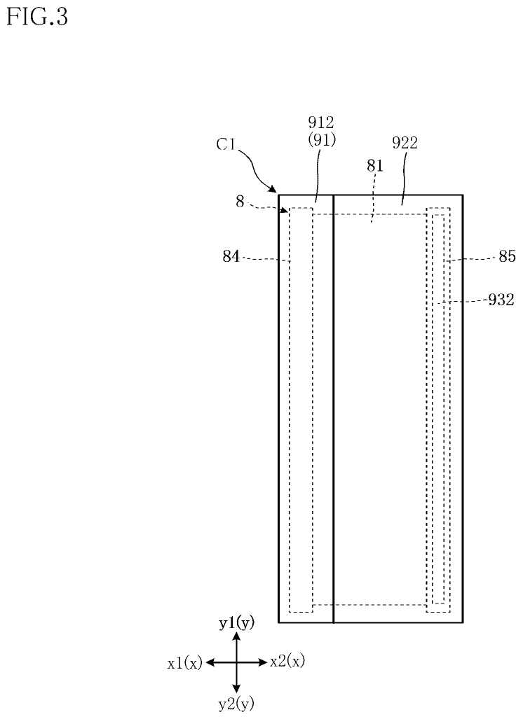

The second external electrode 922 covers at least a part of the reverse covering portion 912. In the example shown in FIGS. 3 and 4, a part of the reverse covering portion 912 is exposed from the second external electrode 922. In the example shown in FIGS. 3 and 4, the second external electrode 922 is formed on the end of the reverse covering portion 912 that is connected to the second side covering portion 914, and the end of the reverse covering portion 912 that is connected to the first side covering portion 913 is exposed. In the example shown in FIGS. 3 and 4, the area of the reverse covering portion 912 that is covered with the second external electrode 922 is larger than the area that is exposed from the second external electrode 922, but the opposite may be the case. Unlike this example, the second external electrode 922 may cover the entire lower surface of the reverse covering portion 912. A larger area in plan view of the second external electrode 922 leads to an increased bonding area to a mounting target and improved heat dissipation to the mounting target. In the example shown in FIG. 3, the second external electrode 922 is rectangular in plan view.

The first conductive member 931 electrically conducts the first external electrode 921 and the capacitor element 8. As shown in FIG. 4, the first conductive member 931 penetrates the insulating cover 91 in the first direction z. The first conductive member 931 is in contact with the first aggregate electrode 84 while being in contact with the first external electrode 921. In the example shown in FIG. 4, the first conductive member 931 overlaps with the first obverse electrode portion 842 in plan view and is in contact with the first obverse electrode portion 842 of the first aggregate electrode 84. The first external electrode 921 and the first aggregate electrode 84 electrically conduct to each other via the first conductive member 931. In the example shown in FIG. 2, the first conductive member 931 has the shape of a strip extending in the third direction y in plan view. Unlike this example, a plurality of columnar (e.g., cylindrical) first conductive members 931 may be disposed along the third direction y.

The second conductive member 932 electrically conducts the second external electrode 922 and the capacitor element 8. As shown in FIG. 4, the second conductive member 932 penetrates the insulating cover 91 in the first direction z. The second conductive member 932 is in contact with the second aggregate electrode 85 while being in contact with the second external electrode 922. In the example shown in FIG. 4, the second conductive member 932 overlaps with the second reverse electrode portion 853 in plan view and is in contact with the second reverse electrode portion 853 of the second aggregate electrode 85. The second external electrode 922 and the second aggregate electrode 85 electrically conduct to each other via the second conductive member 932. In the example shown in FIG. 3, the second conductive member 932 has the shape of a strip extending in the third direction y in plan view. Unlike this example, a plurality of columnar (e.g., cylindrical) second conductive members 932 may be disposed along the third direction y.

The effects of the capacitor device C1 are as follows.

The capacitor device C1 includes the insulating cover 91 covering the capacitor element 8, and the first external electrode 921 and the second external electrode 922 each exposed from the insulating cover 91. The first external electrode 921 and the second external electrode 922 are formed on opposite sides of each other in the first direction z (the lamination direction of the multilayer body 81). Such a configuration makes it possible to mount the capacitor device C1 to two conductors spaced apart in the lamination direction of the multilayer body 81.

The capacitor device C1 includes the capacitor element 8. The capacitor element 8 includes the multilayer body 81 in which the dielectric layers 82 and the conductor layers 83 are alternately laminated in the first direction z. Such a capacitor element 8 is configured in the same manner as existing multilayer ceramic capacitors or existing multilayer film capacitors, and some of existing multilayer ceramic capacitors or existing multilayer film capacitors have high reliability against failure or the like or have high performance (e.g., high capacitance) as a result of various research and development. By including a capacitor element 8 having high reliability and high performance, the capacitor device C1 can be mounted to two conductors spaced apart in the lamination direction of the multilayer body 81 while maintaining reliability and performance.

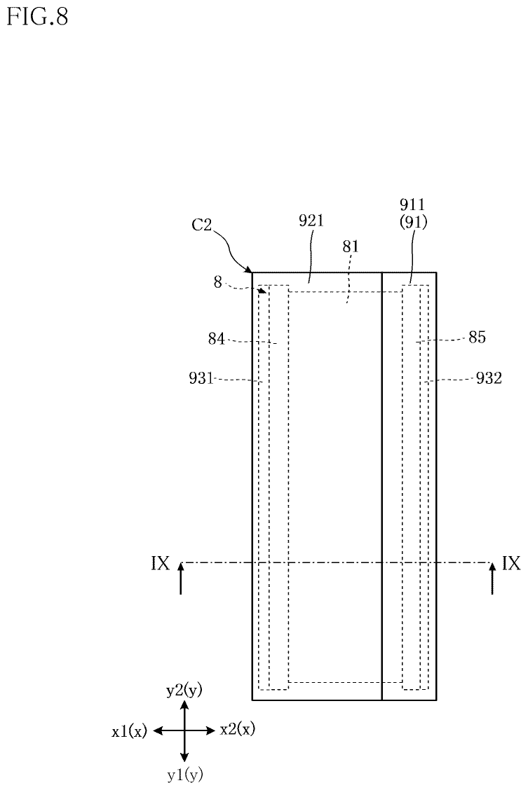

Other embodiments of the capacitor device according to the present disclosure will be described with reference to FIGS. 8 to 25.

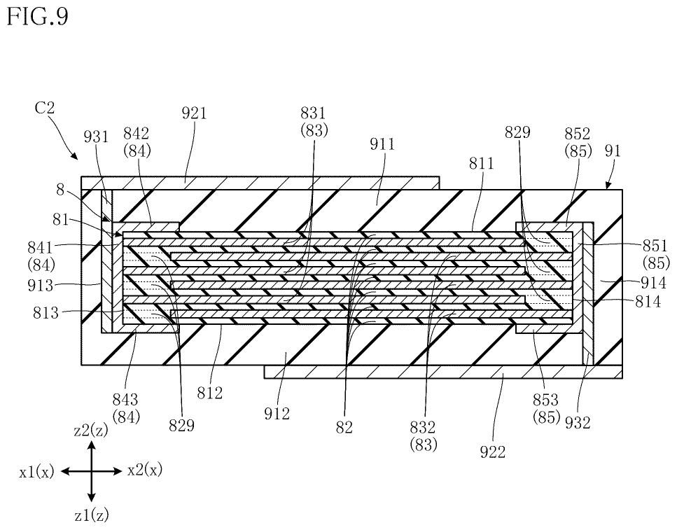

FIGS. 8 and 9 show a capacitor device according to a second embodiment. As shown in FIGS. 8 and 9, the capacitor device C2 according to the second embodiment differs from the capacitor device C1 in the connection position of the first conductive member 931 to the first aggregate electrode 84 and the connection position of the second conductive member 932 to the second aggregate electrode 85.

As shown in FIGS. 8 and 9, in the capacitor device C2, the first conductive member 931 is not in contact with the first obverse electrode portion 842 but in contact with the first side electrode portion 841 of the first aggregate electrode 84. Also, the second conductive member 932 is not in contact with the second reverse electrode portion 853 but in contact with the second side electrode portion 851 of the second aggregate electrode 85.

As with the capacitor device C1, the capacitor device C2 includes the first external electrode 921 and the second external electrode 922 formed on opposite sides of each other in the first direction z (the lamination direction of the multilayer body 81). Thus, as with the capacitor device C1, the capacitor device C2 can be mounted to two conductors spaced apart in the lamination direction of the multilayer body 81.

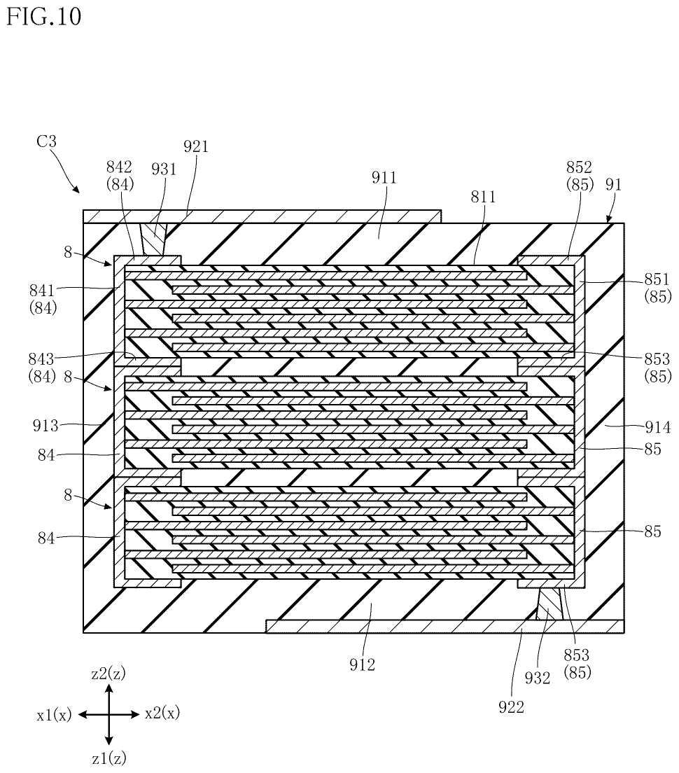

FIG. 10 show a capacitor device according to a third embodiment. As shown in FIG. 10, the capacitor device C3 of the third embodiment differs from the capacitor device C1 in that the capacitor device C3 includes a plurality of capacitor elements 8. In the example shown in FIG. 10, the capacitor device C3 includes three capacitor elements 8. However, the number of capacitor elements 8 is not limited to the illustrated example and may be changed as appropriate depending on the specifications (e.g., capacitance) of the capacitor device C3.

In the capacitor device C3, the plurality of capacitor elements 8 are stacked in the first direction z, as shown in FIG. 10. In any two capacitor elements 8 adjacent in the first direction z, the first obverse electrode portion 842 of the capacitor element 8 located on the z1 side in the first direction and the first reverse electrode portion 843 of the capacitor element 8 located on the z2 side in the first direction are bonded via, for example, a conductive bonding material, not shown. Also, the second obverse electrode portion 852 of the capacitor element 8 located on the z1 side in the first direction and the second reverse electrode portion 853 of the capacitor element 8 located on the z2 side in the first direction are bonded via, for example, a conductive bonding material, not shown. With such a connection relationship, the plurality of capacitor elements 8 are electrically connected in parallel in the capacitor device C3.

In the capacitor device C3, the first conductive member 931 is in contact with the first aggregate electrode 84 of the outermost capacitor element 8 on the z2 side in the first direction and the first external electrode 921, as shown in FIG. 10. The second conductive member 932 is in contact with the second aggregate electrode 85 of the outermost capacitor element 8 on the z1 side in the first direction and the second external electrode 922.

As with the capacitor devices C1 and C2, the capacitor device C3 includes the first external electrode 921 and the second external electrode 922 formed on opposite sides of each other in the first direction z (the lamination direction of the multilayer body 81). Thus, as with the capacitor devices C1 and C2, the capacitor device C3 can be mounted to two conductors spaced apart in the lamination direction of the multilayer body 81.

The capacitor device C3 includes a plurality of capacitor elements 8, and the plurality of capacitor elements 8 are electrically connected in parallel. With such a configuration, the capacitance of the capacitor device C3 is the sum of the capacitances of the plurality of capacitor elements 8. Therefore, the capacitor device C3 can increase the capacitance as compared with the capacitor devices C1 and C2.

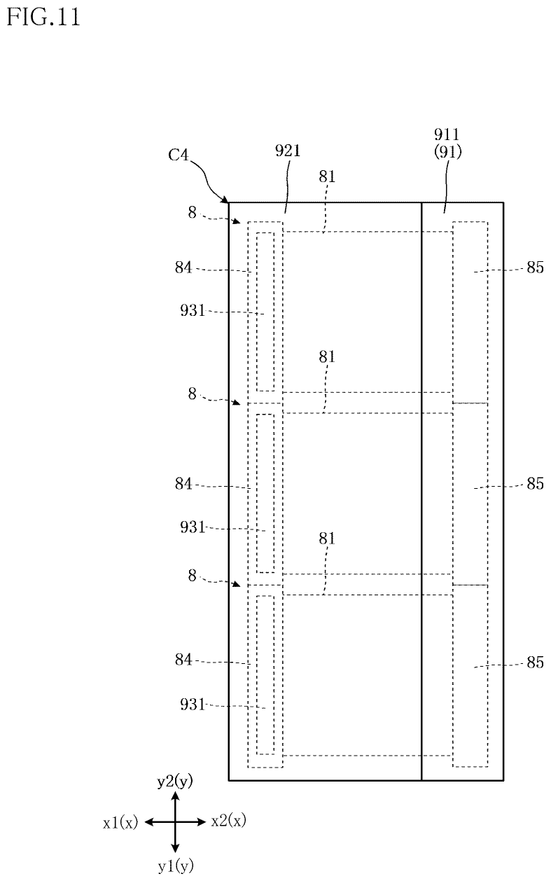

FIG. 11 show a capacitor device according to a fourth embodiment. As shown in FIG. 11, the capacitor device C4 of the fourth embodiment includes a plurality of capacitor elements 8 as with the capacitor device C3, but differs from the capacitor device C3 in the arrangement of the capacitor elements 8. In the example shown in FIG. 11, the capacitor device C4 includes three capacitor elements 8. However, the number of capacitor elements 8 is not limited to the illustrated example.

As shown in FIG. 11, the plurality of capacitor elements 8 are disposed along the third direction y in the capacitor device C4. In any two capacitor elements 8 adjacent in the third direction y, the respective first aggregate electrodes 84 are connected to each other, and the respective second aggregate electrodes 85 are connected to each other. More specifically, in any two capacitor elements 8 adjacent in the third direction y, the portion of the first aggregate electrode 84 that covers the fourth side surface 816 of the capacitor element 8 located on the y1 side in the third direction is connected to the portion of the first aggregate electrode 84 that covers the third side surface 815 of the capacitor element 8 located on the y2 side in the third direction via, for example, a conductive bonding material, not shown. Also, the portion of the second aggregate electrode 85 that covers the fourth side surface 816 of the capacitor element 8 located on the y1 side in the third direction is connected to the portion of the second aggregate electrode 85 that covers the third side surface 815 of the capacitor element 8 located on the y2 side in the third direction via, for example, a conductive bonding material, not shown. With such a connection relationship, the plurality of capacitor elements 8 are electrically connected in parallel in the capacitor device C4, as with the capacitor device C3.

As with the capacitor devices C1 to C3, the capacitor device C4 includes the first external electrode 921 and the second external electrode 922 formed on opposite sides of each other in the first direction z (the lamination direction of the multilayer body 81). Thus, as with the capacitor devices C1 to C3, the capacitor device C4 can be mounted to two conductors spaced apart in the lamination direction of the multilayer body 81.

As with the capacitor device C3, the capacitor device C4 includes a plurality of capacitor elements 8, and the plurality of capacitor elements 8 are electrically connected in parallel. Therefore, as with the capacitor device C3, the capacitor device C4 can increase the capacitance as compared with the capacitor devices C1 and C2.

Comparing the capacitor devices C3 and C4, the capacitor device C3 has a plurality of capacitor elements 8 arranged along the first direction z, whereas the capacitor device C4 has a plurality of capacitor elements 8 arranged along a direction orthogonal to the first direction z (the third direction y). It is preferable to use the capacitor device C3 when the dimension in plan view is limited in the mounting target and use the capacitor device C4 when the dimension in the first direction z is limited in the mounting target.

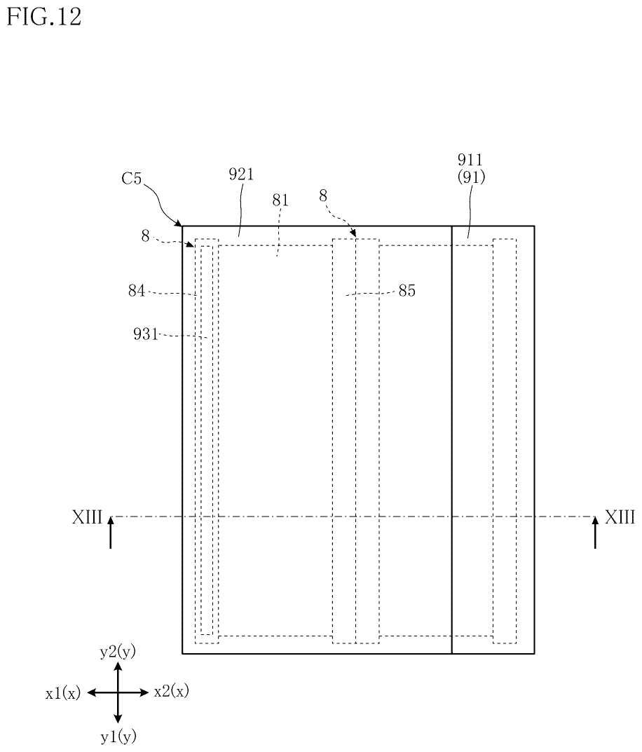

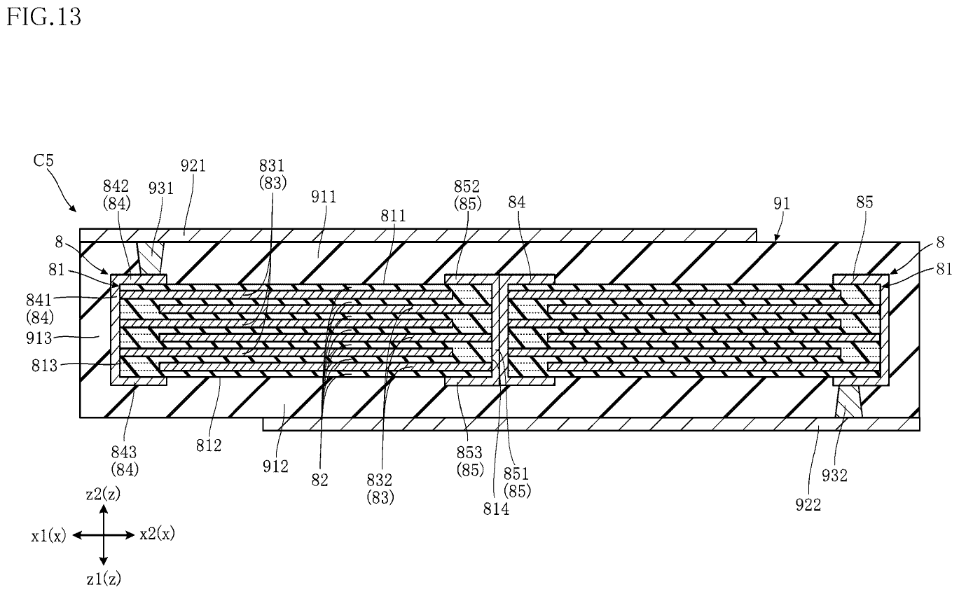

FIGS. 12 and 13 show a capacitor device according to a fifth embodiment. As shown in FIGS. 12 and 13, the capacitor device C5 of the fifth embodiment includes a plurality of capacitor elements 8 as with the capacitor devices C3 and C4, but differs from the capacitor devices C3 and C4 in the connection relationship of the capacitor elements 8. In the example shown in FIG. 12, the capacitor device C5 include two capacitor elements 8. However, the number of capacitor elements 8 is not limited to the illustrated example.

As shown in FIG. 12, the plurality of capacitor elements 8 are disposed along the second direction x in the capacitor device C5. In two capacitor elements 8 adjacent in the second direction x, the second side electrode portion 851 of the capacitor element 8 located on the x1 side in the second direction is bonded to the first side electrode portion 841 of the capacitor element 8 located on the x2 side in the second direction via, for example, a conductive bonding material, not shown. With such a connection relationship, the capacitor elements 8 are electrically connected in series in the capacitor device C5.

In the capacitor device C5, the first conductive member 931 is in contact with the first aggregate electrode 84 of the outermost capacitor element 8 on the x1 side in the second direction and the first external electrode 921. The second conductive member 932 is in contact with the second aggregate electrode 85 of the outermost capacitor element 8 on the x2 side in the second direction and the second external electrode 922.

As with the capacitor devices C1 to C4, the capacitor device C5 includes the first external electrode 921 and the second external electrode 922 formed on opposite sides of each other in the first direction z (the lamination direction of the multilayer body 81). Thus, as with the capacitor devices C1 to C4, the capacitor device C5 can be mounted to two conductors spaced apart in the lamination direction of the multilayer body 81.

The capacitor device C5 includes a plurality of capacitor elements 8 as with the capacitor devices C3 and C4, but the plurality of capacitor elements 8 are electrically connected in series, unlike the capacitor devices C3 and C4. With such a configuration, the voltage applied to each capacitor element 8 is smaller than the voltage applied between the first external electrode 921 and the second external electrode 922.

Thus, the capacitor device C5 can suppress the voltage applied to each capacitor element 8.

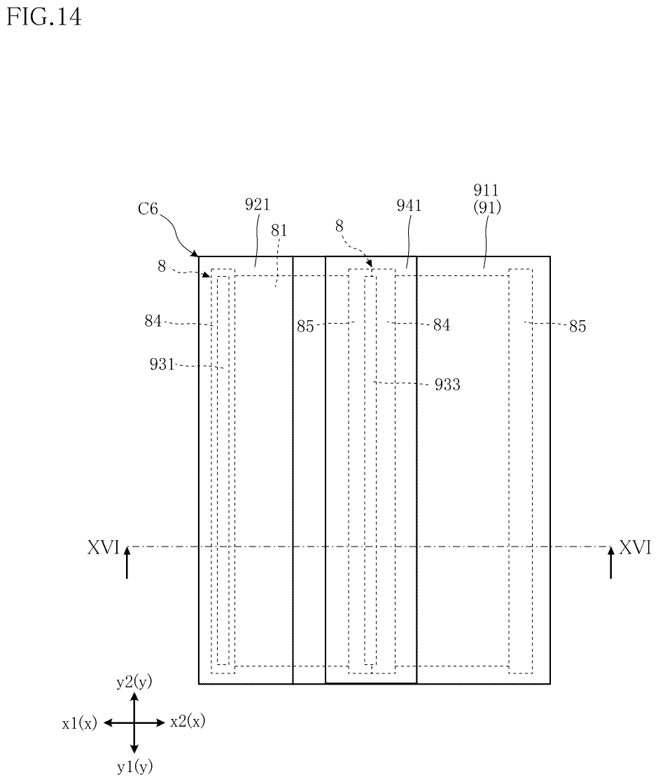

FIGS. 14 to 16 show a capacitor device according to a sixth embodiment. As shown in FIGS. 14 to 16, the capacitor device C6 of the sixth embodiment differs from the capacitor device C5 in that it further includes a first wiring electrode 941, a second wiring electrode 942, a third conductive member 933, and a fourth conductive member 934.

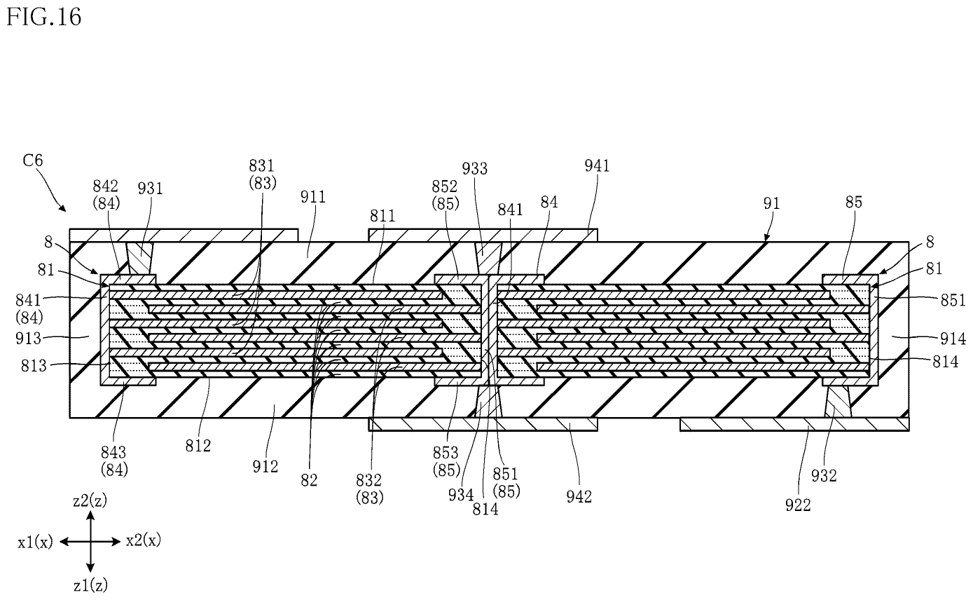

As shown in FIGS. 14 and 16, the first wiring electrode 941 covers a part of the obverse covering portion 911. The first wiring electrode 941 is spaced apart from the first external electrode 921. The constituent material of the first wiring electrode 941 is the same as that of the first external electrode 921, for example.

As shown in FIG. 16, the third conductive member 933 penetrates the obverse covering portion 911 in the first direction z. The third conductive member 933 is in contact with the first wiring electrode 941 and the joint portion of adjacent capacitor elements 8. The joint portion of adjacent capacitor elements 8 means the portion where the second aggregate electrode 85 of the capacitor element 8 located on the x1 side in the second direction and the first aggregate electrode 84 of the capacitor element 8 on the x2 side in the second direction are bonded, and hereinafter referred to as the “series connection portion”. The constituent material of the third conductive member 933 is the same as that of the first conductive member 931, for example.

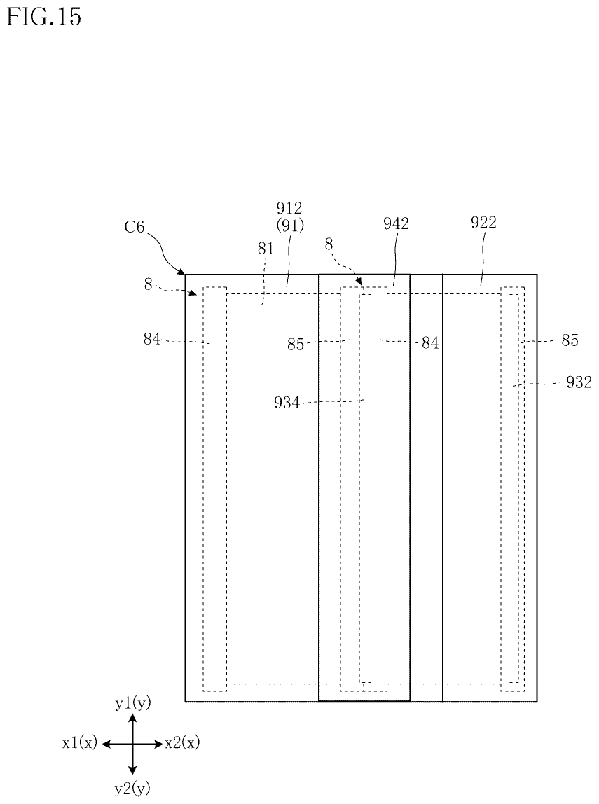

As shown in FIGS. 15 and 16, the second wiring electrode 942 covers a part of the reverse covering portion 912. The second wiring electrode 942 is spaced apart from the second external electrode 922. The constituent material of the second wiring electrode 942 is the same as that of the second external electrode 922, for example.

As shown in FIG. 16, the fourth conductive member 934 penetrates the reverse covering portion 912 in the first direction z. The fourth conductive member 934 is in contact with the second wiring electrode 942 and the series connection portion. The constituent material of the fourth conductive member 934 is the same as that of the second conductive member 932, for example.

As with the capacitor devices C1 to C5, the capacitor device C6 includes the first external electrode 921 and the second external electrode 922 formed on opposite sides of each other in the first direction z (the lamination direction of the multilayer body 81). Thus, as with the capacitor devices C1 to C5, the capacitor device C6 can be mounted to two conductors spaced apart in the lamination direction of the multilayer body 81.

The capacitor device C6 includes the third conductive member 933 and the fourth conductive member 934. With this configuration, the third conductive member 933 and the fourth conductive member 934 function as terminals electrically conducted to the series connection portion (the joint portion where the second aggregate electrode 85 of the capacitor element 8 located on the x1 side in the second direction and the first aggregate electrode 84 of the capacitor element 8 on the x2 side in the second direction are bonded). Therefore, it is possible to detect the potential at the above-described series connection portion using the third conductive member 933 and the fourth conductive member 934. Apart from detecting the potential, the capacitor device C6 can control the potential at the above-described series connection portion as in the following example. At least one of the third conductive member 933 and the fourth conductive member 934 may be connected to the ground (GND) so that the series connection portion is set to the reference potential. In this case, the capacitor device C6 can function as a Y capacitor and hence can reduce the common mode noise.

The capacitor device C6 does not necessarily need to include both the third conductive member 933 and the fourth conductive member 934 and may include only one of them.

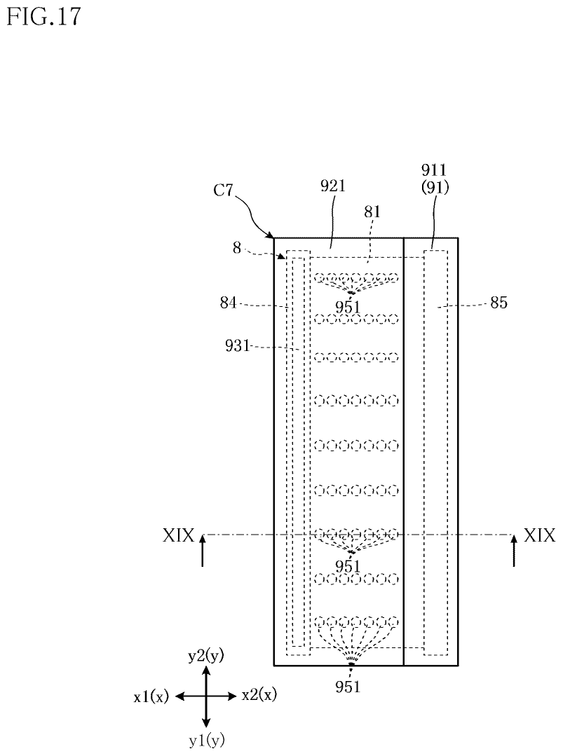

FIGS. 17 to 19 show a capacitor device according to a seventh embodiment. As shown in FIGS. 17 to 19, the capacitor device C7 of the seventh embodiment differs from the capacitor device C1 in that the capacitor device C7 further includes a plurality of first vias 951 and a plurality of second vias 952.

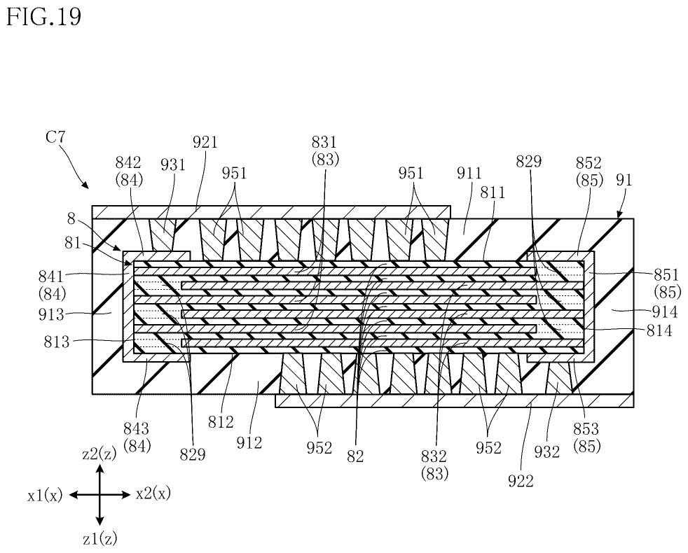

As shown in FIG. 19, the first vias 951 penetrate the obverse covering portion 911 in the first direction z. The first vias 951 are in contact with the obverse surface 811 of the multilayer body 81. The first vias 951 are also in contact with the first external electrode 921. Unlike this configuration, some of the first vias 951 may not be in contact with the first external electrode 921. The constituent material of the first vias 951 is the same as that of the first conductive member 931, for example. The first vias 951 are cylindrical in the example shown in FIGS. 17 and 19, but the first vias 951 are not limited to cylindrical as long as they are columnar. In the example shown in FIG. 17, the plurality of first vias 951 are arranged in a grid pattern.

Unlike this configuration, the first vias 951 may have the shape of a strip elongated in the third direction y in plan view and may be disposed along the second direction x.

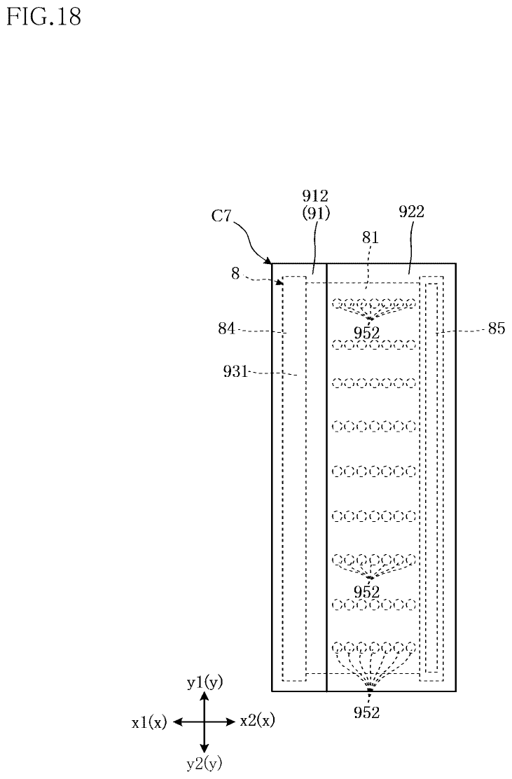

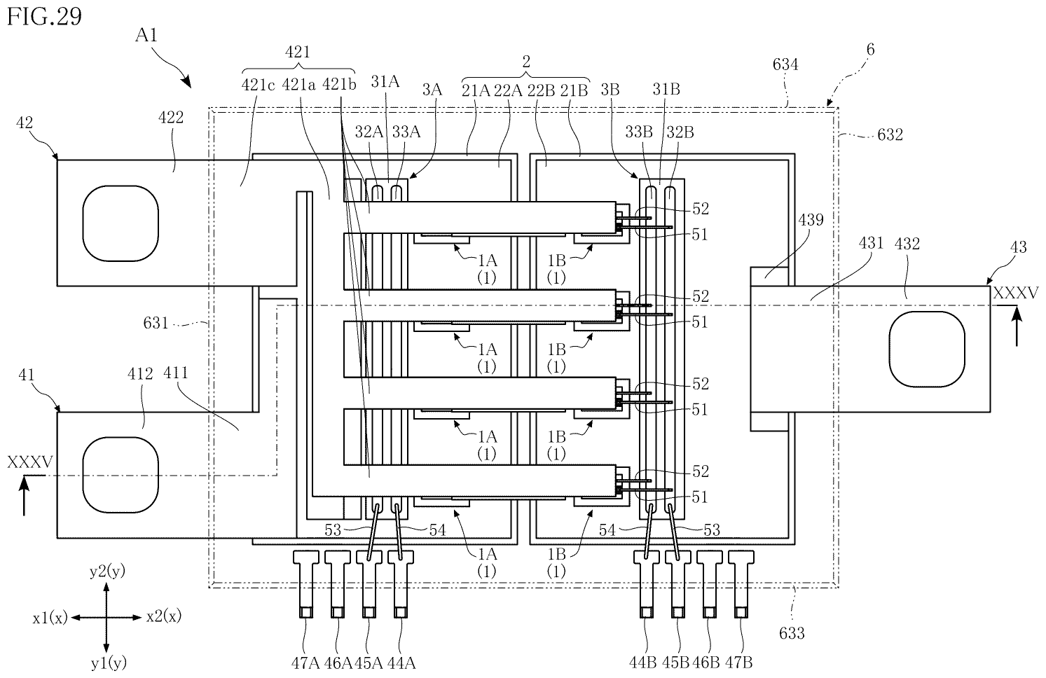

As shown in FIG. 19, the second via 952 penetrate the reverse covering portion 912 in the first direction z. The second vias 952 are in contact with the reverse surface 812 of a dielectric layer 82. The second vias 952 are also in contact with the second external electrode 922. Unlike this configuration, some of the second vias 952 may not be in contact with the second external electrode 922. The constituent material of the second vias 952 is the same as that of the second conductive member 932, for example. The second vias 952 are cylindrical in the example shown in FIGS. 18 and 29, but the second vias 952 are not limited to cylindrical as long as they are columnar. In the example shown in FIG. 18, the second vias 952 are arranged in a grid pattern. Unlike this configuration, the second vias 952 may have the shape of a strip extending in the third direction y in plan view and may be disposed along the second direction x.

As with the capacitor devices C1 to C6, the capacitor device C7 includes the first external electrode 921 and the second external electrode 922 formed on opposite sides of each other in the first direction z (the lamination direction of the multilayer body 81). Thus, as with the capacitor devices C1 to C6, the capacitor device C7 can be mounted to two conductors spaced apart in the lamination direction of the multilayer body 81.

The capacitor device C7 includes the plurality of first vias 951. With this configuration, when the capacitor device C7 is energized, the heat emitted from the multilayer body 81 is transferred through the first vias 951 and dissipated via the first external electrode 921. Thus, the capacitor device C7 can improve the heat dissipation as compared with the capacitor device C1. Also, the capacitor device C7 includes the plurality of second vias 952. With this configuration, when the capacitor device C7 is energized, the heat emitted from the multilayer body 81 is transferred through the second vias 952 and dissipated via the second external electrode 922. Thus, the capacitor device C7 can improve the heat dissipation as compared with the capacitor device C1.

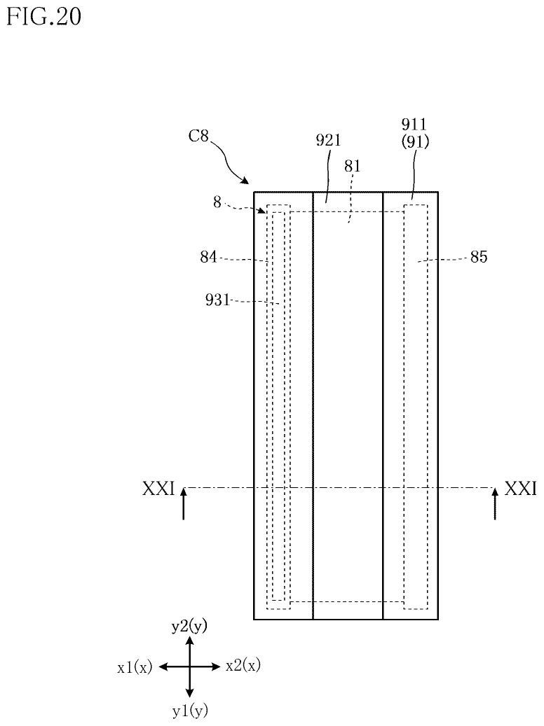

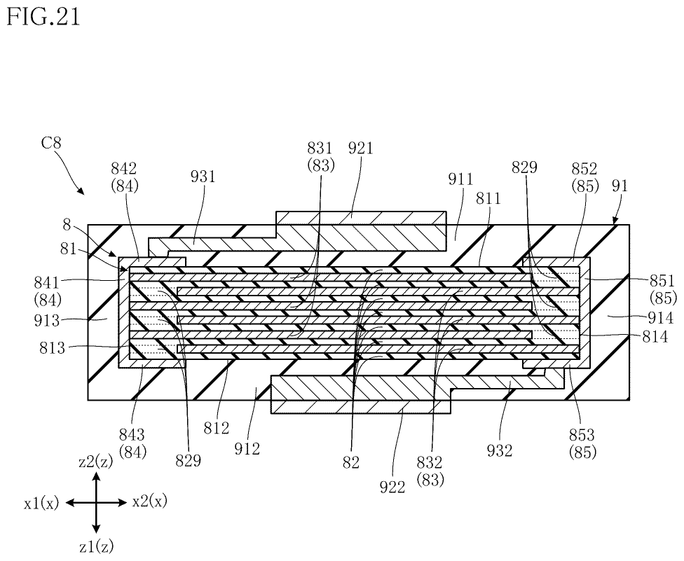

FIGS. 20 and 21 show a capacitor device according to an eighth embodiment. As shown in FIGS. 20 and 21, the capacitor device C8 of the eighth embodiment differs from the capacitor device C1 in the formation range of the first external electrode 921 and the formation range of the second external electrode 922.

In the capacitor device C8, the first external electrode 921 is disposed to cover the area near the center in the second direction x of the obverse covering portion 911 as shown in FIGS. 20 and 21. Correspondingly to this configuration, the first conductive member 931 includes a portion extending along a plane orthogonal to the first direction z (x-y plane) in addition to a portion extending along the first direction z.

In the capacitor device C8, the second external electrode 922 is disposed to cover the area near the center in the second direction x of the reverse covering portion 912 as shown in FIG. 21. Correspondingly to this configuration, the second conductive member 932 includes a portion extending along the x-y plane in addition to a portion extending along the first direction z.

As with the capacitor devices C1 to C7, the capacitor device C8 includes the first external electrode 921 and the second external electrode 922 formed on opposite sides of each other in the first direction z (the lamination direction of the multilayer body 81). Thus, as with the capacitor devices C1 to C7, the capacitor device C8 can be mounted to two conductors spaced apart in the lamination direction of the multilayer body 81.

As understood from the capacitor device C8, the first external electrode 921 can be formed at any location on the obverse covering portion 911 depending on the configuration of the first conductive member 931. That is, the capacitor device of the present disclosure has greater flexibility in the formation position of the first external electrode 921. Similarly, the second external electrode 922 can be formed at any location on the reverse covering portion 912 depending on the configuration of the second conductive member 932. That is, the capacitor device of the present disclosure has greater flexibility in the formation position of the second external electrode 922.

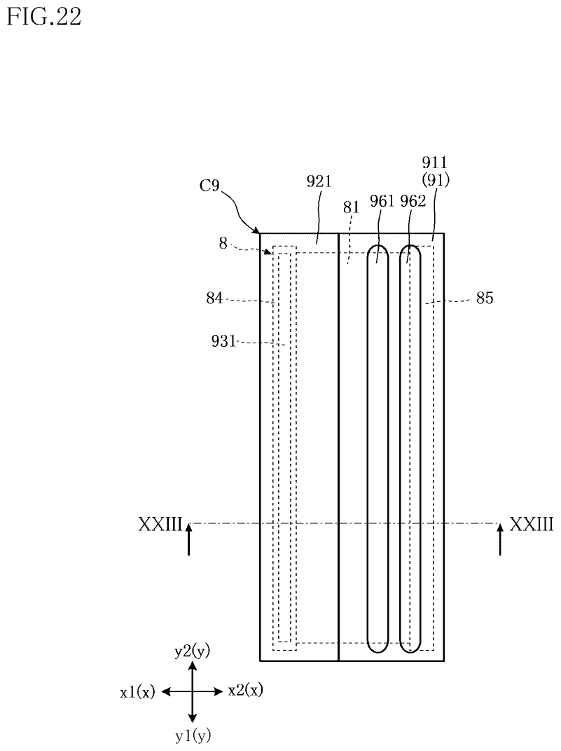

FIGS. 22 and 23 show a capacitor device according to a ninth embodiment. As shown in FIGS. 22 and 23, the capacitor device C9 of the ninth embodiment differs from the capacitor device C1 in that the capacitor device C9 includes a first signal wiring 961 and a second signal wiring 962.

As shown in FIGS. 22 and 23, the first signal wiring 961 and the second signal wiring 962 are formed on a part of the obverse covering portion 911. The first signal wiring 961 and the second signal wiring 962 do not electrically conduct to the multilayer body 81 (the capacitor element 8).

As with the capacitor devices C1 to C8, the capacitor device C9 includes the first external electrode 921 and the second external electrode 922 formed on opposite sides of each other in the first direction z (the lamination direction of the multilayer body 81). Thus, as with the capacitor devices C1 to C8, the capacitor device C9 can be mounted to two conductors spaced apart in the lamination direction of the multilayer body 81.

The capacitor device C9 includes the first signal wiring 961 and the second signal wiring 962 that do not electrically conduct to the multilayer body 81. With this configuration, the first signal wiring 961 and the second signal wiring 962 can be used as wirings for transmitting some signals, so that the capacitor device C9 can be used as a signal substrate having capacitor function.

In the capacitor device C9, the number of signal wirings (the first signal wiring 961 and the second signal wiring 962) is not limited to two, and may be one or three or more.

Each of the capacitor devices C1 to C9 of the first through the ninth embodiments can include the characteristic parts of other capacitor devices.

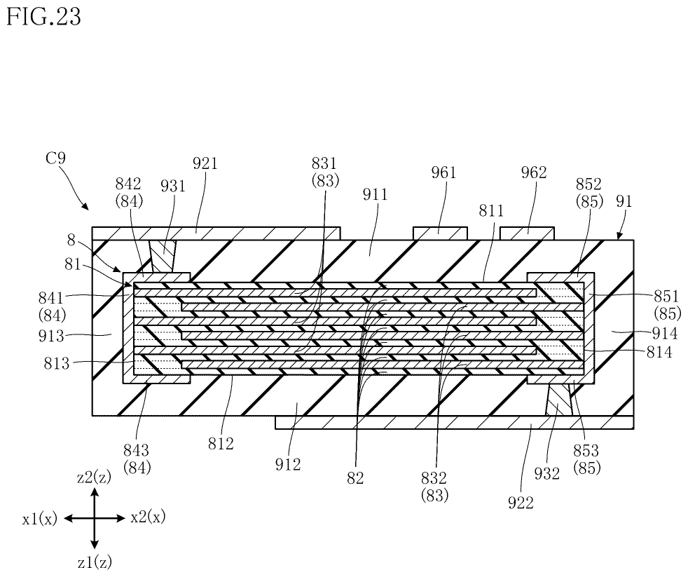

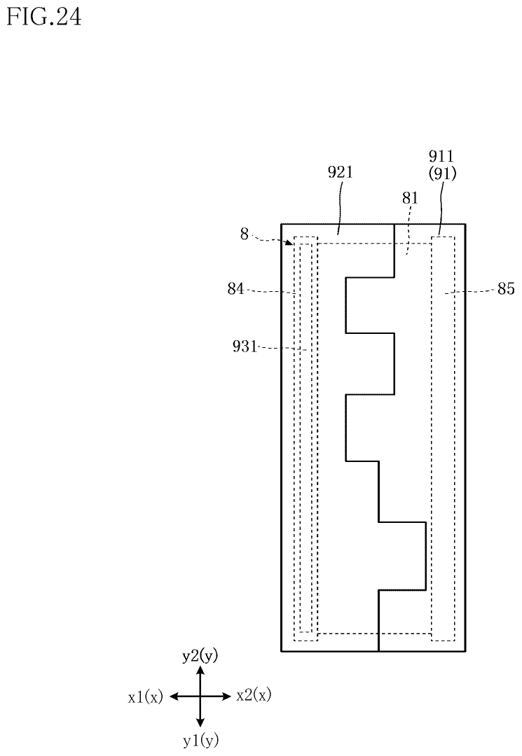

In the capacitor devices C1 to C9 of the first through the ninth embodiments, the shape in plan view of each of the first external electrode 921 and the second external electrode 922 is rectangular. However, the shape in plan view is not limited to a rectangular shape. The first external electrode 921 and the second external electrode 922 can be changed as appropriate depending on the shape of each bonding target (mounting target). FIG. 24 shows a capacitor device according to such a variation and shows the case where the first external electrode 921 is not rectangular. The capacitor device shown in FIG. 24 is one example, and the shape of the first external electrode 921 is not limited to the illustrated example. For example, although the periphery of the first external electrode 921 extends in the second direction x or the third direction y, the periphery may extend diagonally to the second direction x and the third direction y. As understood from the example shown in FIG. 24, forming the first external electrode 921 and the second external electrode 922 as appropriate depending on the shape of each bonding target (mounting target) makes it possible to suppress unintended short circuits and adjust the heat transfer path.

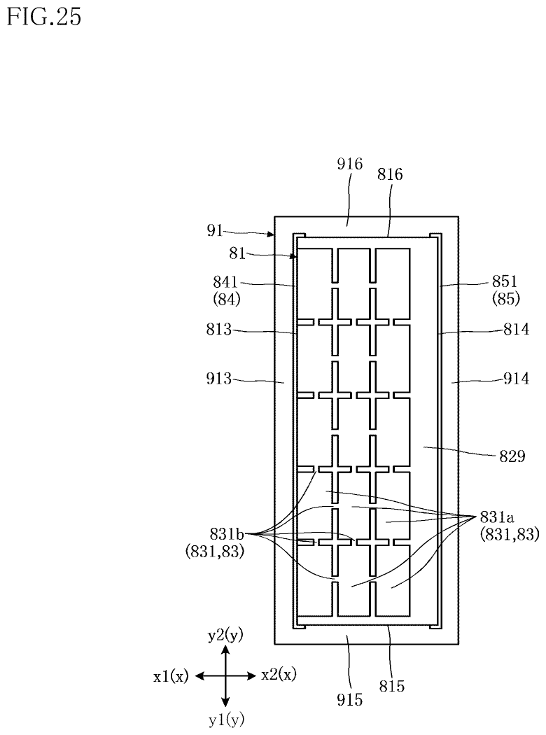

In the capacitor devices C1 to C9 of the first through the ninth embodiments, at least one of the conductor layers 83 (the first electrode layers 831 and the second electrode layers 832), the first external electrode 921 or the second external electrode 922 may include a portion where a conduction path is partially narrowed. FIG. 25 shows a capacitor device according to such a variation and shows an example in which each first electrode layer 831 includes a portion where a conduction path is partially narrowed.

In the example shown in FIG. 25, each first electrode layer 831 includes a plurality of pad pattern portions 831a and a plurality of neck pattern portions 831b. The pad pattern portions 831a are rectangular in plan view. The pad pattern portions 831a are spaced apart from each other and arranged in a grid pattern. Each of the neck pattern portions 831b is the above-described portion where a conduction path is partially narrowed. Each of the neck pattern portions 831b is disposed at the boundary between adjacent pad pattern portions 831a and connects the adjacent pad pattern portions 831a to each other.

In the example shown in FIG. 25, when a defect occurs locally in a dielectric layer 82 in contact with a first electrode layer 831, the insulation properties of the defective portion deteriorates. Such deterioration of the insulation properties causes a current to flow between the first electrode layer 831 and the second electrode layer 832 adjacent to the first electrode layer 831 in the first direction z through the defective portion. That is, the first electrode layer 831 and the second electrode layer 832 are short-circuited. At this time, the current concentrates on the neck pattern portion 831b of the first electrode layer 831, and the neck pattern portion 831b generates heat due to the current concentration and then breaks due to the heat. As a result, the current is interrupted at the pad pattern portion 831a in contact with the defective portion. In this way, the capacitor device shown in FIG. 25 eliminates the short circuit between the first electrode layer 831 and the second electrode layer 832 via the defective portion of the dielectric layer 82, thereby preventing defects (e.g., functional degradation as a capacitor) caused by local defects in the dielectric layer 82.

The neck pattern portions 831b are formed in the first electrode layer 831 in the example shown in FIG. 25. However, as mentioned before, a portion where a conduction path is partially narrowed similarly to the neck pattern portions 831b may be formed in the second electrode layers 832, the first external electrode 921 or the second external electrode 922. Semiconductor device:

Next, a semiconductor device including a capacitor device of the present disclosure will be described.

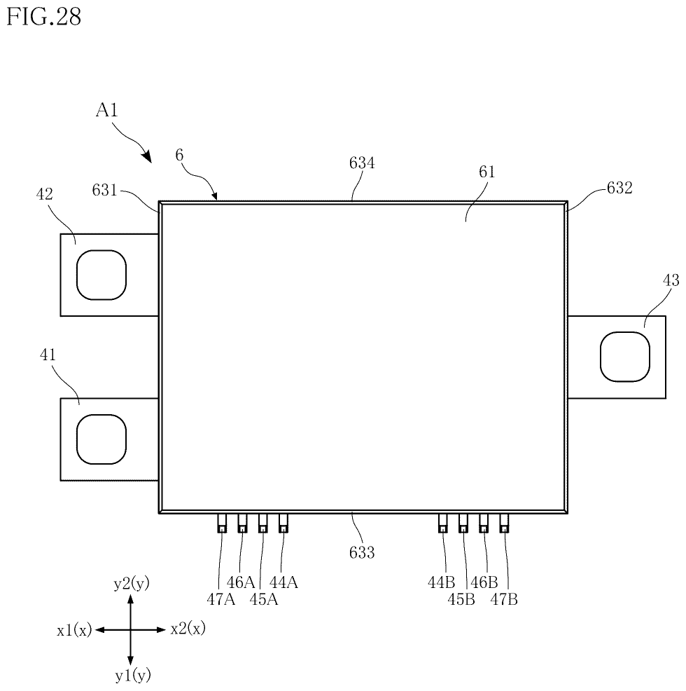

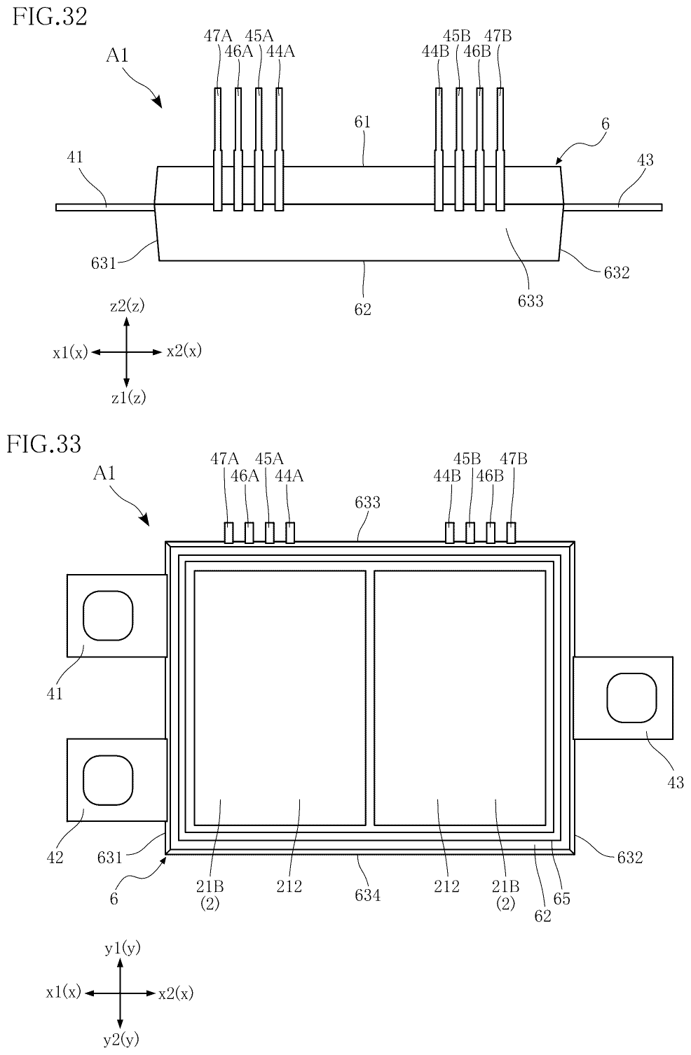

FIGS. 26 to 36 show a semiconductor device A1 according to a first embodiment. The semiconductor device A1 includes the above-described capacitor device C1. As shown in FIGS. 26 to 36, the semiconductor device A1 includes a plurality of switching elements 1, a support substrate 2, a pair of signal substrates 3A and 3B, a pair of input terminals 41 and 42, an output terminal 43, a plurality of signal terminals 44A to 47A and 44B to 47B, a plurality of connecting members 5 and a resin member 6 in addition to the capacitor device C1.

Each of the switching elements 1 includes, for example, a semiconductor material. The semiconductor material is, for example, SiC (silicon carbide). The semiconductor material is not limited to SiC and may be Si (silicon), GaAs (gallium arsenide) or GaN (gallium nitride), for example. Preferably, a wide band gap semiconductor material is used. Each switching element 1 is, for example, a MOSFET. The switching elements 1 are not limited to MOSFETs, but may be other transistors such as field-effect transistors including MISFETs (Metal-Insulator-Semiconductor FETs) or bipolar transistors such as IGBTs. The switching elements 1 are identical with each other and, for example, n-channel MOSFETs. The switching elements 1 are rectangular in plan view but are not limited to this.

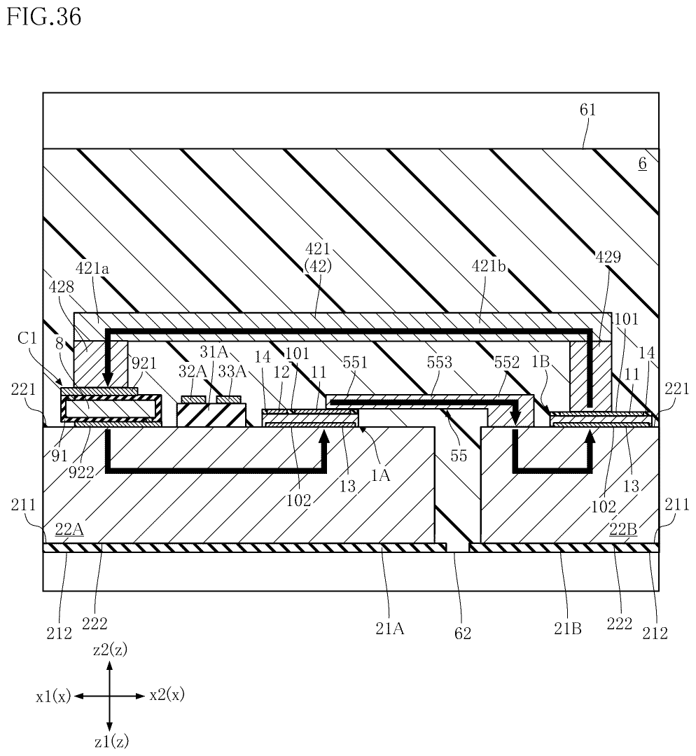

As shown in FIG. 36, each of the switching elements 1 has an element obverse surface 101 and an element reverse surface 102. In each switching element 1, the element obverse surface 101 and the element reverse surface 102 are spaced apart from each other in the first direction z. The element obverse surface 101 faces upward in the first direction z (the z2 side in the first direction), and the element reverse surface 102 faces downward in the first direction z (the z1 side in the first direction).

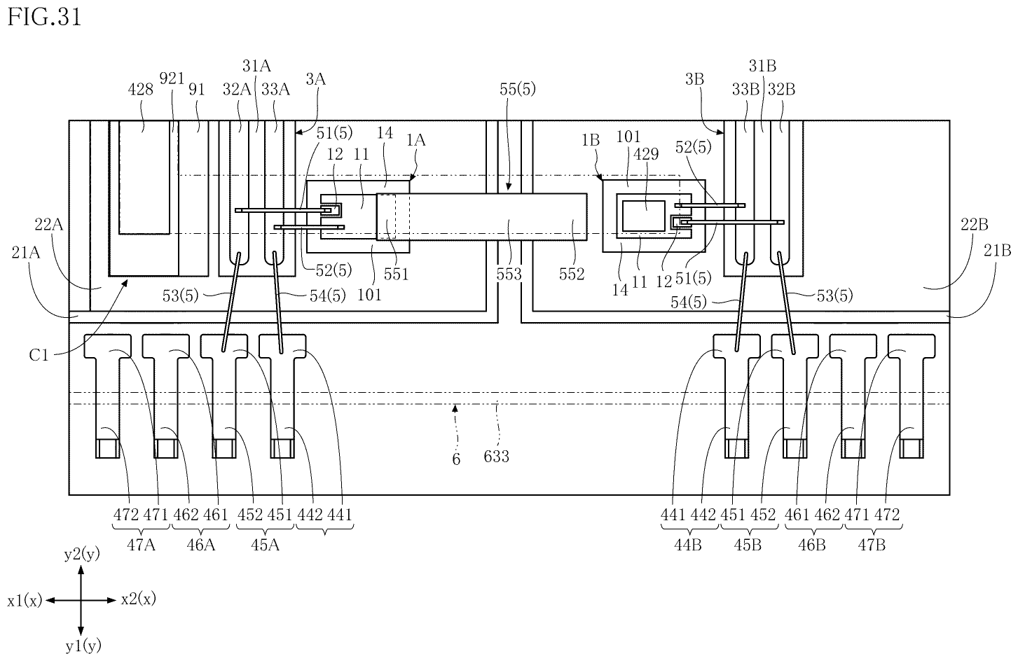

Each of the switching elements 1 has a first electrode 11, a second electrode 12, a third electrode 13, and an insulating film 14. As shown in FIGS. 31 and 36, the first electrode 11 and the second electrode 12 are provided on the element obverse surface 101. The first electrode 11 is, for example, a source electrode, in which a source current flows. The second electrode 12 is, for example, a gate electrode, to which a gate voltage for driving the switching element 1 is applied. In plan view, the first electrode 11 is larger than the second electrode 12. The first electrode 11 is made of a single region in the example shown in FIG. 31, but the first electrode 11 may be divided into a plurality of regions. As shown in FIG. 36, the third electrode 13 is provided on the element reverse surface 102. The third electrode 13 is, for example, a drain electrode, in which a drain current flows. The third electrode 13 is formed over the entire (or almost entire) surface of the element reverse surface 102. As shown in FIGS. 31 and 36, the insulating film 14 is provided on the element obverse surface 101. The insulating film 14 is electrically insulating. The insulating film 14 surrounds the first electrode 11 and the second electrode 12 in plan view. The insulating film 14 insulates the first electrode 11 and the second electrode 12 on the element obverse surface 101. The insulating film 14 is made of, for example, a SiO₂ (silicon dioxide) layer, a SiN₄ (silicon nitride) layer, and a polybenzoxazole layer, laminated in this order on the element obverse surface 101. The composition of the insulating film 14 is not limited to that described above, and for example, a polyimide layer may be laminated instead of the polybenzoxazole layer.

When a drive signal (e.g. a gate voltage) is inputted to the second electrode 12 (the gate electrode), the switching element 1 switches between a conducting state and a disconnected state in accordance with the drive signal. This operation for switching between the conducting state and the disconnected state is referred to as a “switching operation”. In the conducting state, a current flows from the third electrode 13 (the drain electrode) to the first electrode 11 (the source electrode). In the disconnected state, this current does not flow.

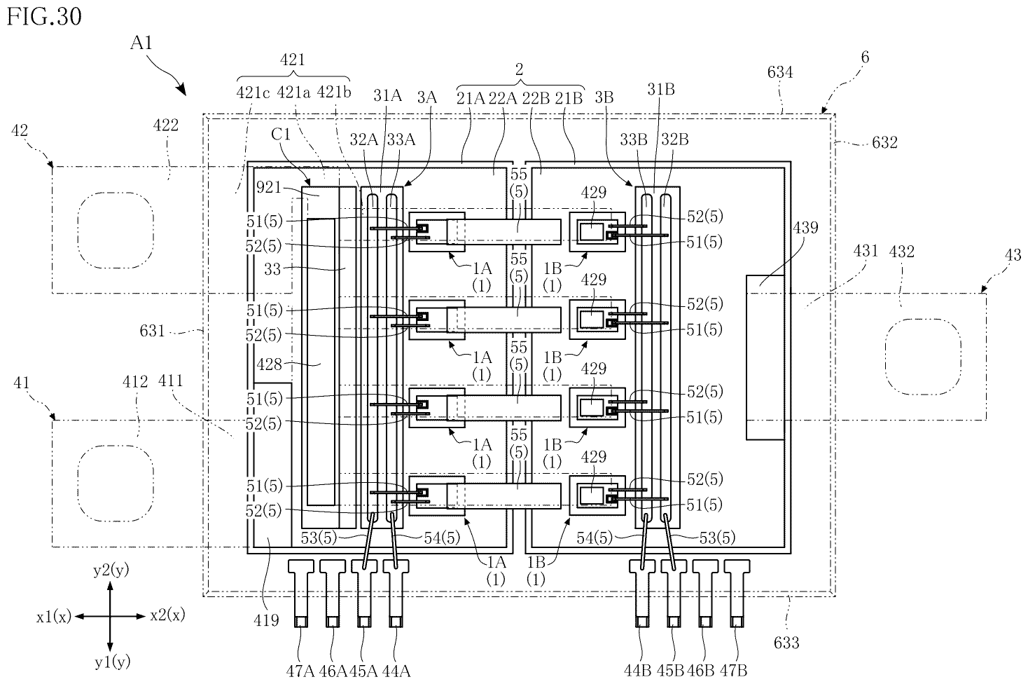

The switching elements 1 include a plurality of switching elements 1A and a plurality of switching elements 1B. In the example shown in FIG. 30, the semiconductor device A1 includes four switching elements 1A and four switching elements 1B. The number of switching elements 1A and 1B is not limited to the present configuration and may be changed as appropriate in accordance with the performance required of the semiconductor device A1. The semiconductor device A1 is, for example, a half-bridge type switching circuit. In this case, the switching elements 1A form the upper arm circuit of the semiconductor device A1, and the switching elements 1B form the lower arm circuit of the semiconductor device A1. The switching elements 1A and the switching elements 1B are connected in series to form a bridge.

As shown in FIGS. 30, 31, 35 and 36, the switching elements 1A are mounted on the support substrate 2. In the example shown in FIG. 30, the switching elements 1A are arranged along the third direction y and spaced apart from each other. The switching elements 1A are conductively bonded to the support substrate 2 (the conductive substrate 22A, described later) via a conductive bonding material, not shown (e.g., sintered metal such as sintered silver or sintered copper, metal paste of silver or copper, or solder). With the switching elements 1A bonded to the conductive substrate 22A, the element reverse surfaces 102 face the conductive substrate 22A. Each switching element 1A is an example of the “first switching element”.

As shown in FIGS. 30, 31, 35 and 36, the switching elements 1B are mounted on the support substrate 2. In the example shown in FIG. 30, the switching elements 1B are arranged along the third direction y and spaced apart from each other. The switching elements 1B are conductively bonded to the support substrate 2 (the conductive substrate 22B, described later) via a conductive bonding material, not shown (e.g., sintered metal such as sintered silver or sintered copper, metal paste of silver or copper, or solder). With the switching elements 1B bonded to the conductive substrate 22B, the element reverse surfaces 102 face the conductive substrate 22B. The switching elements 1A and the switching elements 1B overlap with each other as viewed in the second direction x in the example shown in FIG. 30, but the switching elements 1A and the switching elements 1B may not overlap with each other. Each switching element 1B is an example of the “second switching element”.

The support substrate 2 supports the switching elements 1. The support substrate 2 includes a pair of insulating substrates 21A and 21B and a pair of conductive substrates 22A and 22B.

The pair of insulating substrates 21A and 21B are electrically insulating. The constituent material of the insulating substrates 21A and 21B is, for example, ceramics with excellent thermal conductivity. Examples of such ceramics include AlN (aluminum nitride). The insulating substrates 21A and 21B are not limited to ceramics and may be insulating resin sheets, for example. The insulating substrates 21A and 21B are, for example, rectangular in plan view. The insulating substrates 21A and 21B are arranged along the second direction x and spaced apart from each other. The insulating substrate 21A is located on the x1 side in the second direction with respect to the insulating substrate 21B.

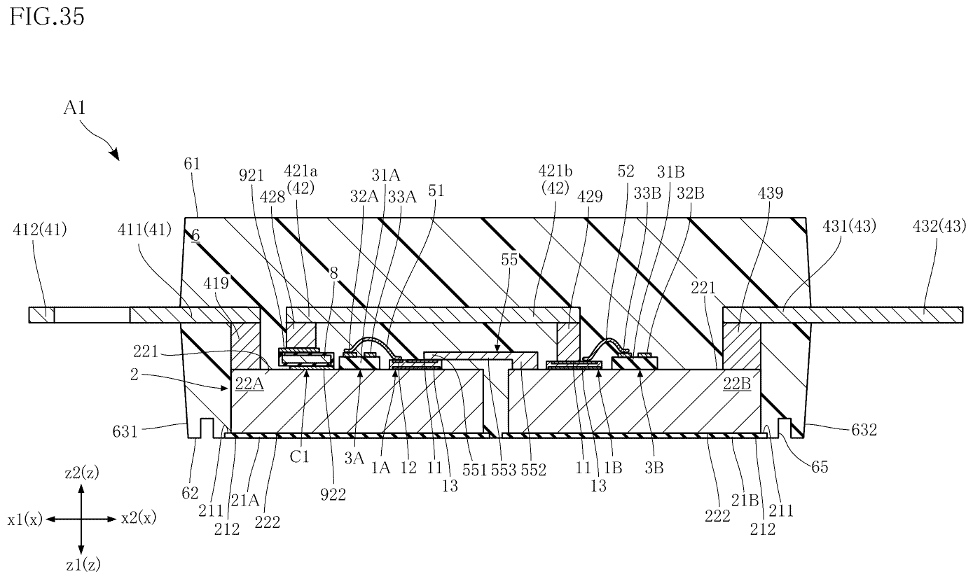

As shown in FIG. 35, each of the insulating substrates 21A and 21B has an obverse surface 211 and a reverse surface 212. In each of the insulating substrates 21A and 21B, the obverse surface 211 and the reverse surface 212 are spaced apart from each other in the first direction z. The obverse surface 211 faces upward in the first direction z, and the reverse surface 212 faces downward in the first direction z. The obverse surface 211 is covered with the resin member 6 together with the conductive substrates 22A and 22B and the switching elements 1. As shown in FIG. 33, the reverse surface 212 is exposed from the resin member 6 (the resin reverse surface 62, described later). A heat sink, not shown, may be connected to the reverse surface 212.

Each of the conductive substrates 22A and 22B is a metal plate. The constituent material of the metal plate is, for example, copper or a copper alloy. The conductive substrates 22A and 22B, together with the two input terminals 41 and 42 and the output terminal 43, form conduction paths to the switching elements 1. The conductive substrates 22A and 22B may be covered with silver plating. The conductive substrates 22A and 22B are spaced apart from each other in the second direction x. In the example shown in FIGS. 30 and 35, the conductive substrate 22A is located on the x1 side in the second direction with respect to the conductive substrate 22B.

As shown in FIG. 35, each of the conductive substrates 22A and 22B has an obverse surface 221 and a reverse surface 222. In each of the conductive substrates 22A and 22B, the obverse surface 221 and the reverse surface 222 are spaced apart from each other in the first direction z. The obverse surface 221 faces upward in the first direction z, and the reverse surface 222 faces downward in the first direction z.

As shown in FIG. 35, the conductive substrate 22A is bonded to the insulating substrate 21A via a bonding material, not shown. This bonding material may be either conductive or insulating. With the conductive substrate 22A bonded to the insulating substrate 21A, the reverse surface 222 of the conductive substrate 22A faces the obverse surface 211 of the insulating substrate 21A. The switching elements 1A, the signal substrate 3A and the capacitor device C1 are mounted on the obverse surface 221 of the conductive substrate 22A. The conductive substrate 22A in the present embodiment is an example of the “first mount portion”.

As shown in FIG. 35, the conductive substrate 22B is bonded to the insulating substrate 21B via a bonding material, not shown. This bonding material may be either conductive or insulating. With the conductive substrate 22B bonded to the insulating substrate 21B, the reverse surface 222 of the conductive substrate 22B faces the obverse surface 211 of the insulating substrate 21B. The switching elements 1B and the signal substrate 3B are mounted on the obverse surface 221 of the conductive substrate 22B. The conductive substrate 22B in the present embodiment is an example of the “second mount portion”.

The configuration of the support substrate 2 is not limited to the above-described example. For example, two conductive substrates 22A and 22B may be bonded to a single insulating substrate. A metal layer may be formed on the reverse surface 222 of each of the insulating substrates 21A and 21B. The shape, size and arrangement of the insulating substrates 21A and 21B and the conductive substrates 22A and 22B may be changed as appropriate based on the number, arrangement or the like of the switching elements 1.

The signal substrates 3A and 3B relay various signals between the switching elements 1 and the signal terminals 44A to 47A or 44B to 47B. The signal substrate 3A includes an insulating layer 31A, a gate layer 32A and a detection layer 33A, and the signal substrate 3B includes an insulating layer 31B, a gate layer 32B and a detection layer 33B.

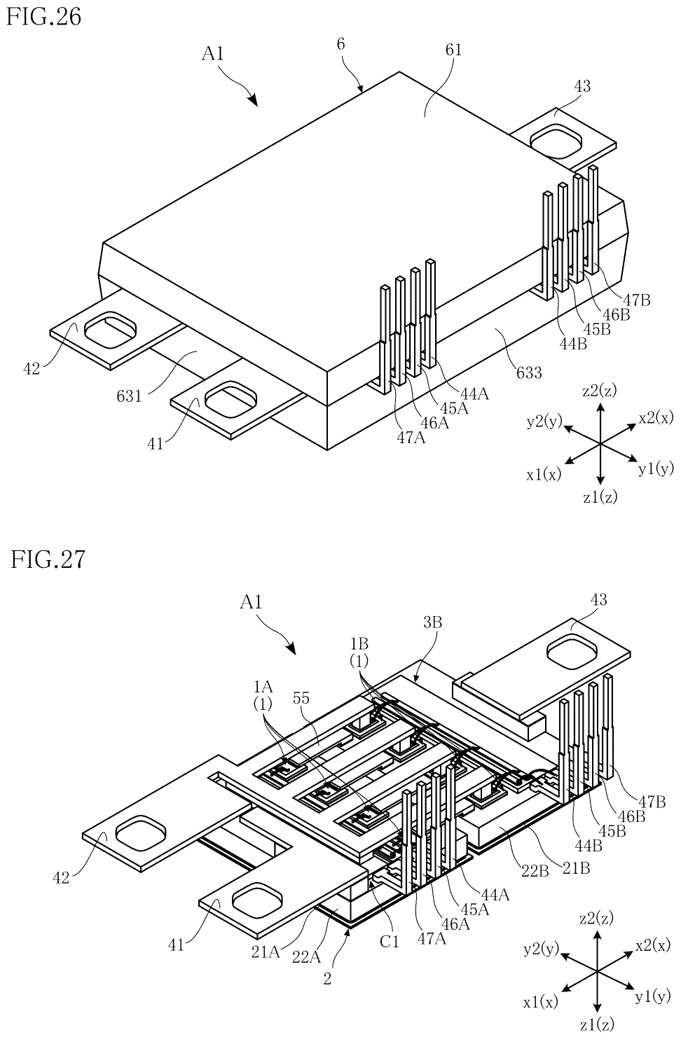

The insulating layers 31A and 31B are electrically insulating, and their constituent material is, for example, glass epoxy resin. As shown in FIGS. 27 and 29, each of the insulating layers 31A and 31B has the shape of a strip extending in the third direction y.

As shown in FIGS. 35 and 36, the insulating layer 31A is bonded to the obverse surface 221 of the conductive substrate 22A. As shown in FIG. 30, the insulating layer 31A is located on the x1 side in the second direction with respect to the switching elements 1A.

As shown in FIGS. 35 and 36, the insulating layer 31B is bonded to the obverse surface 221 of the conductive substrate 22B. As shown in FIG. 30, the insulating layer 31B is located on the x2 side in the second direction with respect to the switching elements 1B.

The gate layers 32A and 32B have electrical conductivity, and their constituent material is, for example, copper or a copper alloy. As shown in FIGS. 29 and 30, each of the gate layers 32A and 32B has the shape of a strip extending in the third direction y.

As shown in FIGS. 35 and 36, the gate layer 32A is disposed on the insulating layer 31A. The gate layer 32A electrically conducts to the second electrode 12 (the gate electrode) of each switching element 1A via a connecting member 5 (a gate wire 51, described later).

As shown in FIGS. 35 and 36, the gate layer 32B is disposed on the insulating layer 31B. The gate layer 32B electrically conducts to the second electrode 12 (the gate electrode) of each switching element 1B via a connecting member 5 (a gate wire 51, described later).

The detection layers 33A and 33B have electrical conductivity, and their constituent material is, for example, copper or a copper alloy. As shown in FIGS. 29 and 30, each of the detection layers 33A and 33B has the shape of a strip extending in the third direction y.

As shown in FIGS. 35 and 36, the detection layer 33A is disposed on the insulating layer 31A together with the gate layer 32A. As shown in FIG. 30, the detection layer 33A is located next to the gate layer 32A and spaced apart from the gate layer 32A in plan view. The detection layer 33A is parallel to the gate layer 32A in plan view. The detection layer 33A is disposed closer to the switching elements 1A than is the gate layer 32A in the second direction x. The detection layer 33A is located on the x2 side in the second direction with respect to the gate layer 32A. The positional relationship between the gate layer 32A and the detection layer 33A in the second direction x may be opposite to the illustrated example. The detection layer 33A electrically conducts to the first electrode 11 (the source electrode) of each switching element 1A via a connecting member 5 (a detection wire 52, described later).

As shown in FIGS. 35 and 36, the detection layer 33B is disposed on the insulating layer 31B together with the gate layer 32B. As shown in FIG. 30, the detection layer 33B is located next to the gate layer 32B and spaced apart from the gate layer 32B in plan view. The detection layer 33B is parallel to the gate layer 32B in plan view. The detection layer 33B is disposed closer to the switching elements 1B than is the gate layer 32B. The detection layer 33B is located on the x1 side in the second direction with respect to the gate layer 32B. The positional relationship between the gate layer 32B and the detection layer 33B in the second direction x may be opposite to the illustrated example. The detection layer 33B electrically conducts to the first electrode 11 (the source electrode) of each switching element 1B via a connecting member 5 (a detection wire 52, described later).

Each of the two input terminals 41 and 42 is made of a metal plate. The constituent material of the metal plate is copper or a copper alloy. As shown in FIGS. 26 to 30, the two input terminals 41 and 42 are located on one side in the second direction x in the semiconductor device A1. A power supply voltage, for example, is applied between the two input terminals 41 and 42. The input terminal 41 is a positive electrode (P terminal), and the input terminal 42 is a negative electrode (N terminal). The input terminal 41 and the input terminal 42 are spaced apart from each other.

As shown in FIGS. 29 and 30, the input terminal 41 includes a pad portion 411 and a terminal portion 412.

The pad portion 411 is a portion of the input terminal 41 that is covered with the resin member 6. As shown in FIGS. 30 and 35, the pad portion 411 is conductively bonded to the conductive substrate 22A via a conductive block 419. The pad portion 411 is bonded to the block 419 via a conductive bonding material, not shown, and the block 419 is bonded to the conductive substrate 22A via a conductive bonding material, not shown. In this way, the input terminal 41 and the conductive substrate 22A electrically conduct to each other. The constituent material of the block 419 is not particularly limited, and copper, a copper alloy, a CuMo (copper molybdenum) composite, or a CIC (Copper-Invar-Copper) composite may be used, for example. The bonding of the pad portion 411 and the block 419 and the bonding of the block 419 and the conductive substrate 22A are not limited to the bonding using a conductive bonding material, and laser welding, ultrasonic bonding or the like may be used. Also, the bonding of the pad portion 411 and the conductive substrate 22A is not limited to the bonding via the block 419. For example, a part of the pad portion 411 may be bent so that the pad portion 411 is directly bonded to the conductive substrate 22A.

The terminal portion 412 is a portion of the input terminal 41 that is exposed from the resin member 6. As shown in FIG. 29, the terminal portion 412 extends from the resin member 6 toward the above-mentioned one side in the second direction x in plan view. The terminal portion 412 is, for example, rectangular in plan view.

As shown in FIGS. 29 and 30, the input terminal 42 includes a pad portion 421 and a terminal portion 422.

The pad portion 421 is a portion of the input terminal 42 that is covered with the resin member 6. As shown in FIG. 29, the pad portion 421 includes a joining portion 421a, a plurality of extending portions 421b, and a connecting portion 421c.

As shown in FIG. 29, the joining portion 421a has, for example, the shape of a strip extending in the third direction y. As shown in FIGS. 30, 35 and 36, the joining portion 421a is bonded to the first external electrode 921 of the capacitor device C1 via a conductive block 428. The joining portion 421a is bonded to the block 428 via a conductive bonding material, not shown, and the block 428 is bonded to the first external electrode 921 of the capacitor device C1 via a conductive bonding material, not shown. In this way, the input terminal 42 and the first external electrode 921 electrically conduct to each other. The constituent material of the block 428 is not particularly limited, and copper, a copper alloy, a CuMo composite, or a CIC composite may be used, for example. The bonding of the joining portion 421a and the block 428 and the bonding of the block 428 and the first external electrode 921 are not limited to the bonding using a conductive bonding material, and laser welding, ultrasonic bonding or the like may be used.

As shown in FIG. 29, each of the extending portions 421b has, for example, the shape of a strip extending from the joining portion 421a toward the other side in the second direction x. Each extending portion 421b extends in the second direction x from the joining portion 421a until it overlaps with a switching element 1B in plan view. The extending portions 421b are arranged along the third direction y and spaced apart from each other in plan view. As shown in FIGS. 30 and 35, each extending portion 421b is bonded to a switching element 1B at its extremity via a conductive block 429. As shown in FIGS. 35 and 36, the extremity of each extending portion 421b is bonded to a block 429 via a conductive bonding material, not shown, and the block 429 is bonded to the first electrode 11 of a switching element 1B via a conductive bonding material, not shown. In this way, the input terminal 42 and the first electrodes 11 of the switching elements 1B electrically conduct to each other. The constituent material of the block 429 is not particularly limited, and copper, a copper alloy, a CuMo composite, or a CIC composite may be used, for example. The bonding of the extending portions 421b and the blocks 429 and the bonding of the blocks 429 and the first electrodes 11 are not limited to the bonding using a conductive bonding material, and laser welding, ultrasonic bonding or the like may be used. Also, the bonding of the extending portions 421b and the first electrodes 11 of the switching elements 1B is not limited to the bonding via the blocks 429. For example, a part of each extending portion 421b may be bent so that the extending portion 421b is directly bonded to the first electrode 11 of a switching element 1B.

As shown in FIG. 29, the connecting portion 421c is a portion that connects the joining portion 421a and the terminal portion 422.

The terminal portion 422 is a portion of the input terminal 42 that is exposed from the resin member 6. As shown in FIG. 29, the terminal portion 422 extends from the resin member 6 toward the x1 side in the second direction in plan view. As shown in FIG. 29, the terminal portion 422 is located on the y2 side in the third direction of the terminal portion 412 of the input terminal 41 in plan view. The shape in plan view of the terminal portion 422 is, for example, the same as that of the terminal portion 412.

The output terminal 43 is made of a metal plate. The constituent material of the metal plate is, for example, copper or a copper alloy. As shown in FIGS. 26 to 30, the output terminal 43 is located on the x2 side in the second direction in the semiconductor device A1. The AC power (voltage) converted by the switching elements 1 is outputted from the output terminal 43.

As shown in FIG. 29, the output terminal 43 includes a pad portion 431 and a terminal portion 432.

The pad portion 431 is a portion of the output terminal 43 that is covered with the resin member 6. As shown in FIGS. 30 and 35, the pad portion 431 is conductively bonded to the conductive substrate 22B via a conductive block 439. As shown in FIG. 35, the pad portion 431 is bonded to the block 439 via a conductive bonding material, not shown, and the block 439 is bonded to the conductive substrate 22B via a conductive bonding material, not shown. In this way, the output terminal 43 and the conductive substrate 22B electrically conduct to each other. The constituent material of the block 439 is not particularly limited, and copper, a copper alloy, a CuMo composite, or a CIC composite may be used, for example. The bonding of the pad portion 431 and the block 439 and the bonding of the block 439 and the conductive substrate 22B are not limited to the bonding using a conductive bonding material, and laser welding, ultrasonic bonding, or the like may be used. Also, the bonding of the pad portion 431 and the conductive substrate 22B is not limited to the bonding via the block 439. For example, a part of the pad portion 431 may be bent so that the pad portion 431 is directly bonded to the conductive substrate 22B.

The terminal portion 432 is a portion of the output terminal 43 that is exposed from the resin member 6. As shown in FIG. 29, the terminal portion 432 extends from the resin member 6 toward the x2 side in the second direction. The terminal portion 432 is, for example, rectangular in plan view.

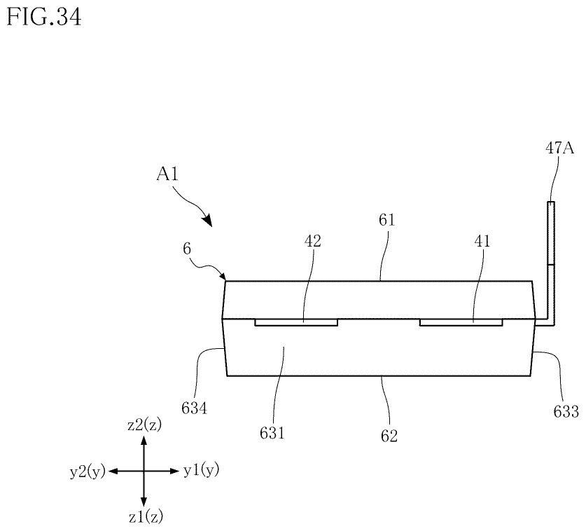

The signal terminals 44A to 47A and 44B to 47B are terminals for inputting or outputting control signals of the semiconductor device A1. Examples of the control signals include signals for controlling the switching operation of the switching elements 1. The signal terminals 44A to 47A and 44B to 47B have the same (or approximately the same) shape. Each of the signal terminals 44A to 47A and 44B to 47B is L-shaped as viewed in the second direction x. As shown in FIGS. 26 to 33, the signal terminals 44A to 47A and 44B to 47B are arranged in the second direction x. As shown in FIG. 34, the signal terminals 44A to 47A and 44B to 47B overlap with each other as viewed in the second direction x. As shown in FIG. 30, the signal terminals 44A to 47A are located next to the conductive substrate 22A in the third direction y in plan view, and the signal terminals 44B to 47B are located next to the conductive substrate 22B in the third direction y in plan view. The signal terminals 44A to 47A and 44B to 47B project from, for example, the surface of the resin member 6 that faces the y1 side in the third direction (the resin side surface 633, described later). The signal terminal 44A to 47A and 44B to 47B are formed from a same lead frame.

As shown in FIGS. 30 and 31, the signal terminals 44A and 44B electrically conduct to the detection layers 33A and 33B, respectively, via connecting members 5 (second connection wires 54, described later). The voltage applied to the first electrode 11 of each switching element 1A (the voltage corresponding to the source current) is detected at the signal terminal 44A. The signal terminal 44A is the source signal detection terminal of the switching elements 1A. The voltage applied to the first electrode 11 of each switching element 1B (the voltage corresponding to the source current) is detected at the signal terminal 44B. The signal terminal 44B is the source signal detection terminal of the switching elements 1B.

As shown in FIG. 31, each of the signal terminals 44A and 44B includes a pad portion 441 and a terminal portion 442. In each of the signal terminals 44A and 44B, the pad portion 441 is covered with the resin member 6. Thus, the signal terminals 44A and 44B are supported by the resin member 6. The terminal portion 442 is connected to the pad portion 441 and exposed from the resin member 6. Each of the signal terminals 44A and 44B is bent at the terminal portion 442.

As shown in FIGS. 30 and 31, the signal terminals 45A and 45B electrically conduct to the gate layers 32A and 32B, respectively, via connecting members 5 (first connection wires 53, described later). A drive signal (gate voltage) for driving the switching elements 1A is applied to the signal terminal 45A. The signal terminal 45A is a terminal for inputting a drive signal for the switching elements 1A (gate signal input terminal). A drive signal (gate voltage) for driving the switching elements 1B is applied to the signal terminal 45B. The signal terminal 45B is a terminal for inputting a drive signal for the switching elements 1B (gate signal input terminal).

As shown in FIG. 31, each of the signal terminals 45A and 45B includes a pad portion 451 and a terminal portion 452. In each of the signal terminals 45A and 45B, the pad portion 451 is covered with the resin member 6. Thus, the signal terminals 45A and 45B are supported by the resin member 6. The terminal portion 452 is connected to the pad portion 451 and exposed from the resin member 6. Each of the signal terminals 45A and 45B is bent at the terminal portion 452.

As shown in FIGS. 30 and 31, the signal terminals 46A, 46B, 47A, and 47B do not electrically conduct to other structural elements. The semiconductor device A1 may not include the signal terminals 46A, 46B, 47A, and 47B.

As shown in FIG. 31, each of the signal terminals 46A and 46B includes a pad portion 461 and a terminal portion 462. In each of the signal terminals 46A and 46B, the pad portion 461 is covered with the resin member 6. Thus, the signal terminals 46A and 46B are supported by the resin member 6. The terminal portion 462 is connected to the pad portion 461 and exposed from the resin member 6. Each of the signal terminals 46A and 46B is bent at the terminal portion 462. Each of the signal terminals 47A and 47B includes a pad portion 471 and a terminal portion 472. In each of the signal terminals 47A and 47B, the pad portion 471 is covered with the resin member 6. Thus, the signal terminals 47A and 47B are supported by the resin member 6. The terminal portion 472 is connected to the pad portion 471 and exposed from the resin member 6. Each of the signal terminals 47A and 47B is bent at the terminal portion 472.

Each of the connecting members 5 electrically conducts two members that are spaced apart from each other. As shown in FIG. 30, the connecting members 5 include a plurality of gate wires 51, a plurality of detection wires 52, a pair of first connection wires 53, a pair of second connection wires 54, and a plurality of lead members 55.

The gate wires 51, the detection wires 52, the first connection wires 53, and the second connection wires 54 are so-called bonding wires, and their constituent material is, for example, aluminum, gold, or copper.

As shown in FIGS. 30 and 31, each of the gate wires 51 has one end bonded to the second electrode 12 (gate electrode) of a switching element 1, and the other end bonded to one of the gate layers 32A and 32B. The plurality of gate wires 51 include those that electrically conduct the second electrodes 12 of the switching elements 1A and the gate layer 32A, and those that electrically conduct the second electrodes 12 of the switching elements 1B and the gate layer 32B.

As shown in FIGS. 30 and 31, each of the detection wires 52 has one end bonded to the first electrode 11 (source electrode) of a switching element 1, and the other end bonded to one of the detection layers 33A and 33B. The plurality of detection wires 52 include those that electrically conduct the first electrodes 11 of the switching elements 1A and the detection layer 33A, and those that electrically conduct the first electrodes 11 of the switching elements 1B and the detection layer 33B.

As shown in FIGS. 30 and 31, one of the pair of first connection wires 53 connects the gate layer 32A and the signal terminal 45A (gate signal input terminal), and the other one connects the gate layer 32B and the signal terminal 45B (gate signal input terminal). The above-mentioned one of the first connection wires 53 has one end bonded to the gate layer 32A and the other end bonded to the pad portion 451 of the signal terminal 45A, thereby electrically conducting these to each other. The above-mentioned other one of the first connection wires 53 has one end bonded to the gate layer 32B and the other end bonded to the pad portion 451 of the signal terminal 45B, thereby electrically conducting these to each other.

As shown in FIGS. 30 and 31, one of the pair of second connection wires 54 connects the detection layer 33A and the signal terminal 44A (source signal detection terminal), and the other one connects the detection layer 33B and the signal terminal 44B (source signal detection terminal). The above-mentioned one of the second connection wires 54 has one end bonded to the detection layer 33A and the other end bonded to the pad portion 441 of the signal terminal 44A, thereby electrically conducting these to each other. The above-mentioned other one of the second connection wires 54 has one end bonded to the detection layer 33B and the other end bonded to the pad portion 441 of the signal terminal 44B, thereby electrically conducting these to each other.

Each of the lead members 55 is made of a conductive material, which is, for example, aluminum, gold, or copper. In the semiconductor device A1, a bonding wire may be used instead of each lead member 55. As shown in FIGS. 30, 31, and 36, each lead member 55 electrically conducts the first electrode 11 of a switching element 1A and the conductive substrate 22B. As shown in FIGS. 30 and 31, each lead member 55 has the shape of a strip extending in the second direction x in plan view.

As shown in FIGS. 31, 35 and 36, each lead member 55 includes a first bonding portion 551, a second bonding portion 552, and a link portion 553. The first bonding portion 551 is a portion of the lead member 55 that is connected to a switching element 1A. The first bonding portion 551 is bonded to the first electrode 11 of the switching element 1A via a conductive bonding material, not shown. The first bonding portion 551 overlaps with the first electrode 11 of the switching element 1A in plan view. The second bonding portion 552 is a portion of the lead member 55 that is bonded to the conductive substrate 22B. The second bonding portion 552 is bonded to the obverse surface 221 of the conductive substrate 22B via a conductive bonding material, not shown. The second bonding portion 552 and the conductive substrate 22B may be directly bonded by laser welding or ultrasonic welding. The second bonding portion 552 overlaps with the conductive substrate 22B in plan view. The thickness (the dimension in the first direction z) of the second bonding portion 552 is larger than the thickness (the dimension in the first direction z) of the first bonding portion 551. The link portion 553 is a portion of the lead member 55 that is connected to the first bonding portion 551 and the second bonding portion 552. The thickness (the dimension in the first direction z) of the link portion 553 is the same (or approximately the same) as the thickness (the dimension in the first direction z) of the first bonding portion 551. The link portion 553 bridges between the conductive substrate 22A and the conductive substrate 22B in plan view.

As shown in FIGS. 29, 30 and 35, the resin member 6 covers the switching elements 1, the support substrate 2 (except the reverse surfaces 212 of the insulating substrates 21A and 21B), the signal substrates 3A and 3B, a part of each of the two input terminals 42, a part of the output terminal 43, a part of each of the signal terminals 44A to 47A and 44B to 47B, and the connecting members 5. The constituent material of the resin member 6 is, for example, an epoxy resin. As shown in FIGS. 29, 30 and 35, the resin member 6 includes a resin obverse surface 61, a resin reverse surface 62, and a plurality of resin side surfaces 631 to 634.

As shown in FIG. 35, the resin obverse surface 61 and the resin reverse surface 62 are spaced apart from each other in the first direction z. The resin obverse surface 61 faces the z2 side in the first direction, and the resin reverse surface 62 faces the z1 side in the first direction. As shown in FIG. 33, the resin reverse surface 62 has the shape of a frame surrounding the reverse surfaces 212 of the insulating substrates 21A and 21B in plan view. The reverse surfaces 212 of the insulating substrates 21A and 21B are exposed from the resin reverse surface 62.

Each of the resin side surfaces 631 to 634 is connected to both the resin obverse surface 61 and the resin reverse surface 62 and located between these surfaces in the first direction z. The resin side surface 631 and the resin side surface 632 are spaced apart from each other in the second direction x. The resin side surface 631 faces the x1 side in the second direction, and the resin side surface 632 faces the x2 side in the second direction. The two input terminals 41 and 42 protrude from the resin side surface 631, and the output terminal 43 protrudes from the resin side surface 632. The resin side surface 633 and the resin side surface 634 are spaced apart from each other in the third direction y. The resin side surface 633 faces the y1 side in the third direction, and the resin side surface 634 faces the y2 side in the third direction. The signal terminals 44A to 47A and 44B to 47B protrude from the resin side surface 633.

As shown in FIGS. 33 and 35, the resin member 6 includes a recess 65 that is recessed from the resin reverse surface 62 in the first direction z. As shown in FIG. 33, the recess 65 has the shape of a loop surrounding the support substrate 2 in plan view. The resin member 6 may not be formed with the recess 65.

The capacitor device C1 is mounted on the conductive substrate 22A. As shown in FIGS. 35 and 36, the capacitor device C1 is conductively bonded, via a conductive bonding material, not shown (e.g., solder, metal paste, or sintered metal), to the conductive substrate 22A at the second external electrode 922. In the capacitor device C1, the block 428 is conductively bonded to the first external electrode 921 via a conductive bonding material, not shown. The first external electrode 921 of the capacitor device C1 electrically conducts to the joining portion 421a of the input terminal 42 via the block 428. In the semiconductor device A1, the capacitor device C1 has a capacitance of 500 nF or less, for example.

In the semiconductor device A1, the distance between the capacitor device C1 and each switching element 1A in the second direction x is not particularly limited, but is preferably 2 cm or less to reduce the parasitic inductance between the capacitor device C1 and each switching element 1A.

The effects of the semiconductor device A1 are as follows.

The semiconductor device A1 includes the capacitor device C1. The capacitor device C1 has the first external electrode 921 and the second external electrode 922 that are disposed on opposite sides in the first direction z and bonded to the block 428 and the conductive substrate 22A, respectively, which are spaced apart from each other in the first direction z. In a configuration that does not include the capacitor device C1 unlike the semiconductor device A1, there is space between the pad portion 421 and the conductive substrate 22A in the first direction z in the state before the resin member 6 is formed. If the capacitor described in Patent Document 1 is used for such a configuration, it is difficult to place the capacitor device in this space and electrically connect the pad portion 421 and the conductive substrate 22A using the mounting method described in Patent Document 2. In contrast, because the capacitor device C1 has the first external electrode 921 and the second external electrode 922 disposed on opposite sides in the first direction z, it is possible to place the capacitor device C1 in the above-described space and electrically connect the pad portion 421 and the conductive substrate 22A (via the block 428). In other words, because the capacitor device C1 can be mounted between two conductors spaced apart from each other in the first direction z (the lamination direction of the multilayer body 81), the semiconductor device A1 can contain the capacitor device C1 in the above-described space. That is, the semiconductor device A1 can incorporate the capacitor device C1 by using the feature of the capacitor device C1.

In the semiconductor device A1, each of the switching elements 1A and 1B has the first electrode 11 and the third electrode 13. In the example where each of the switching elements 1A and 1B is a MOSFET, the first electrode 11 is a source electrode, and the third electrode 13 is a drain electrode. The second external electrode 922 of the capacitor device C1 electrically conducts to the third electrode 13 of each switching element 1A via the conductive substrate 22A. The first electrode 11 of each switching element 1A electrically conducts to the third electrode 13 of a switching element 1B via a lead member 55 and the conductive substrate 22B. The third electrode 13 of each switching element 1B electrically conducts to the first external electrode 921 of the capacitor device C1 via the block 429, the input terminal 42 (the pad portion 421), and the block 428. Such a configuration forms a current path (see the bold arrows in FIG. 36) from the capacitor device C1 (the second external electrode 922) to the capacitor device C1 (the first external electrode 921) through the conductive substrate 22A, each switching element 1A (from the third electrode 13 to the first electrode 11), each lead member 55, the conductive substrate 22B, each switching element 1B (from the third electrode 13 to the first electrode 11), each block 429, the input terminal 42 (the pad portion 421) and the block 428 in this order. The semiconductor device A1 reduces the internal inductance by forming such a current path. Preferably, the semiconductor device A1 reduces the internal inductance to 10 nH or less by the current path, which is effective in suppressing the internal loss and noise generation in the semiconductor device A1.

In the semiconductor device A1, the second external electrode 922 is bonded to the conductive substrate 22A. With such a configuration, when the semiconductor device A1 is energized, the heat generated by the capacitor device C1 is conducted to the conductive substrate 22A. Also, in the capacitor device C1, on the lower side in the first direction z of the multilayer body 81, the second external electrode 922 is disposed, and the first external electrode 921 is not disposed. Therefore, the capacitor device C1 can have a larger contact area with the conductive substrate 22A as compared with a conventional chip-type capacitor. Thus, the semiconductor device A1 can increase the contact area between the capacitor device C1 and the conductive substrate 22A to improve the heat dissipation from the capacitor device C1.

In the semiconductor device A1, the capacitor device C1 is bonded to the conductive substrate 22A together with the switching elements 1A. With this configuration, when the semiconductor device A1 is energized, the heat generated by the capacitor device C1 is diffused by the conductive substrate 22A and dissipated to the outside through the conductive substrate 22A and the insulating substrate 21A. Because the switching elements 1A are also bonded to the conductive substrate 22A, the heat generated by the switching elements 1A is also diffused by the conductive substrate 22A and dissipated to the outside through the conductive substrate 22A and the insulating substrate 21A. That is, the heat dissipation path for the capacitor device C1 is the same as that for each switching element 1A. Thus, the semiconductor device A1 can improve the heat dissipation of the capacitor device C1.

Although the semiconductor device A1 includes the capacitor device C1 in the above example, it may include the capacitor device C2 to C8 instead of the capacitor device C1.

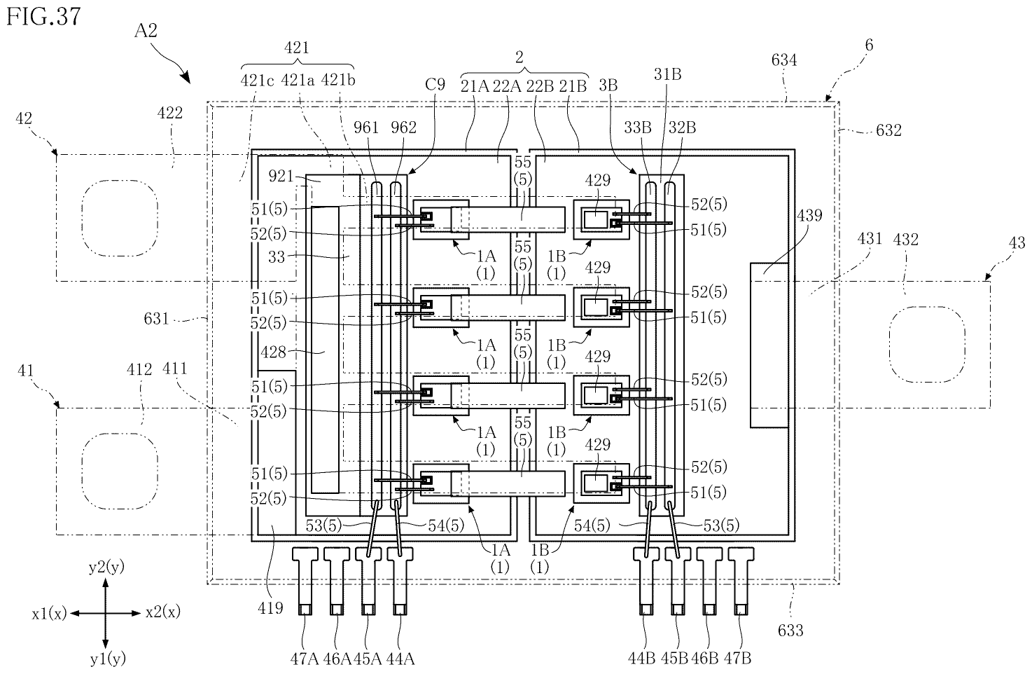

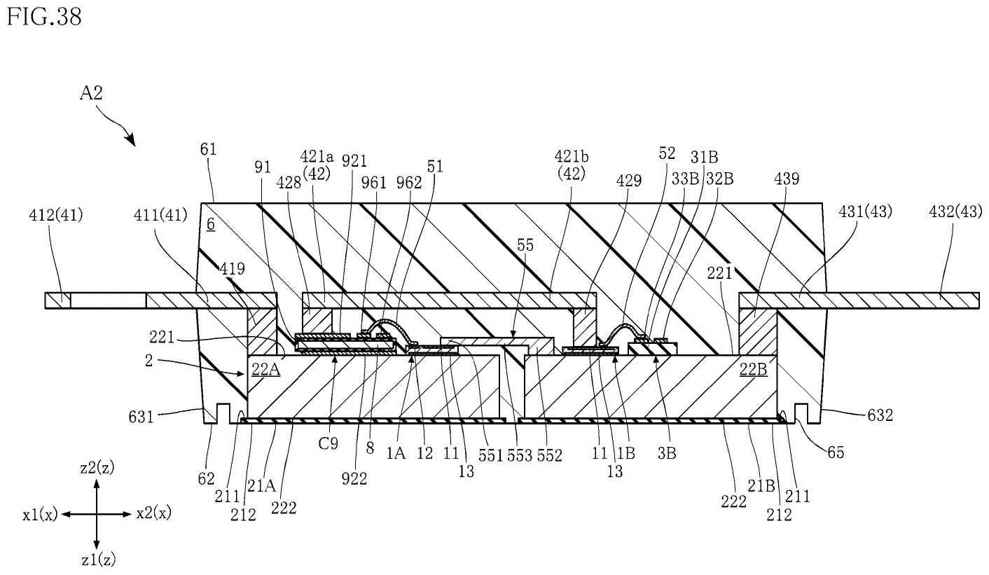

FIGS. 37 and 38 show a semiconductor device A2 according to a second embodiment. As shown in FIGS. 37 and 38, the semiconductor device A2 differs from the semiconductor device A1 in the following points. First, the semiconductor device A2 includes the above-described capacitor device C9 instead of the capacitor device C1. Second, the semiconductor device A2 does not include the signal substrate 3A.

As shown in FIG. 37, in the semiconductor device A2, the first signal wiring 961 of the capacitor device C9 has the gate wires 51 and a first connection wire 53 connected thereto, instead of the gate layer 32A of the signal substrate 3A. The first signal wiring 961 electrically conducts to the second electrodes 12 (the gate electrodes) of the switching elements 1A via the gate wires 51 and electrically conducts to the signal terminal 45A via the first connection wire 53. The first signal wiring 961 is a transmission path of a drive signal for driving each switching element 1A.

As shown in FIG. 37, in the semiconductor device A2, the second signal wiring 962 of the capacitor device C9 has the detection wires 52 and a second connection wire 54 connected thereto, instead of the detection layer 33A of the signal substrate 3A. The second signal wiring 962 electrically conducts to the first electrodes 11 (the source electrodes) of the switching elements 1A via the detection wires 52 and electrically conducts to the signal terminal 44A via the second connection wire 54. The second signal wiring 962 is a transmission path for a signal (the voltage corresponding to the source current) indicating the conduction state of each switching element 1A.

The semiconductor device A2 can achieve the same effects as the semiconductor device A1. Furthermore, the semiconductor device A2 eliminates the need for the signal substrate 3A by including the capacitor device C9 instead of the capacitor device C1.

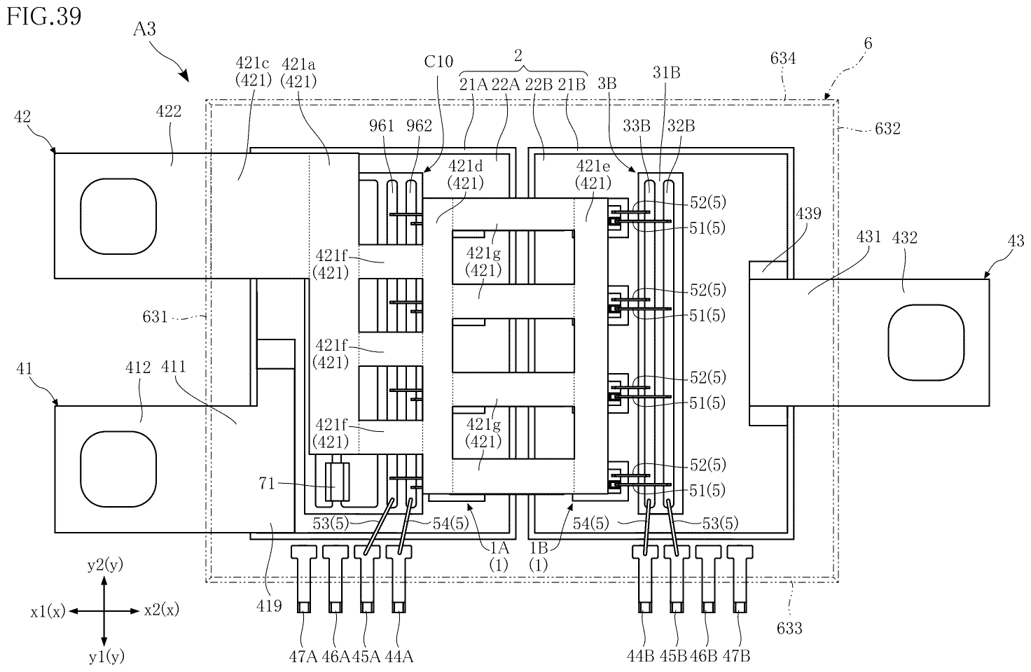

FIGS. 39 to 43 show a semiconductor device A3 according to a third embodiment. As shown in FIGS. 39 to 43, the semiconductor device A3 differs from the semiconductor device A2 in the following points. First, the semiconductor device A3 includes the capacitor device C10 instead of the capacitor device C9. Second, the semiconductor device A3 includes a plurality of passive elements 71. Thirdly, the semiconductor device A3 has an input terminal 42 of a different shape.

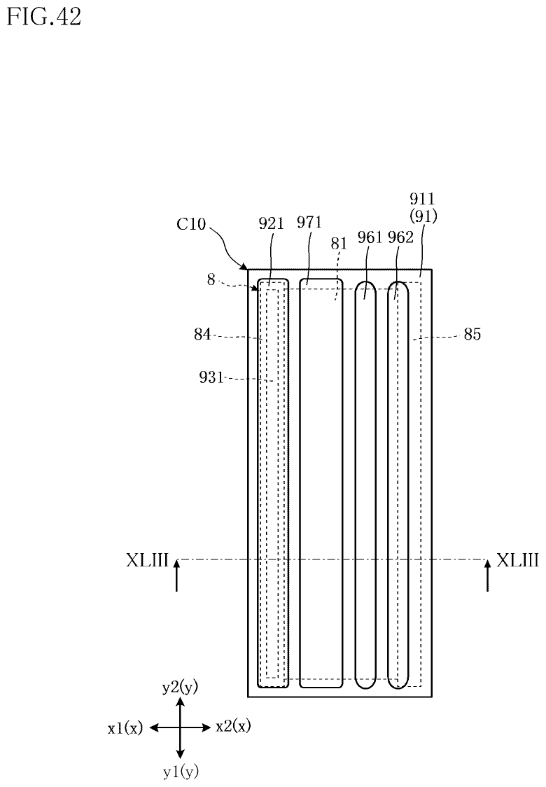

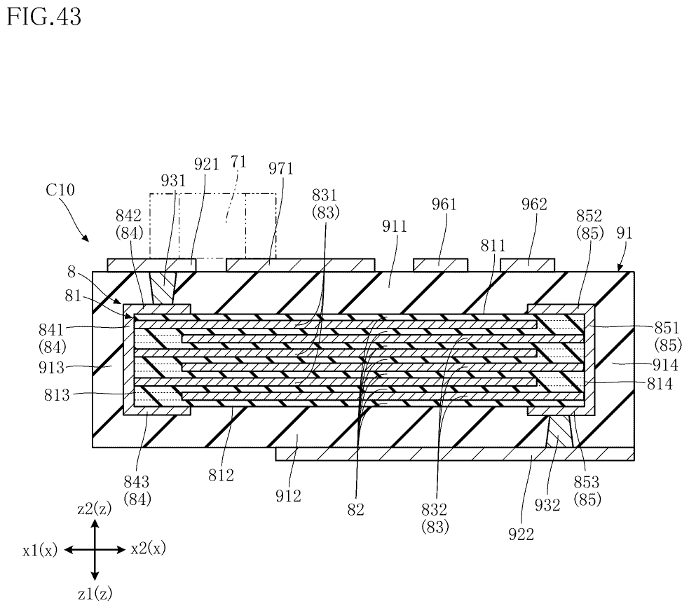

As shown in FIGS. 42 and 43, as a difference from the capacitor device C9, the capacitor device C10 further includes an external wiring 971.

As shown in FIG. 43, the external wiring 971 is formed on a part of the obverse covering portion 911 as with the first external electrode 921, the first signal wiring 961, and the second signal wiring 962. The external wiring 971 is not connected to a wiring penetrating the obverse covering portion 911, and does not electrically conduct to the multilayer body 81 (the capacitor element 8) in the capacitor device C10 alone. In the example shown in FIGS. 42 and 43, the external wiring 971 is disposed between the first external electrode 921 and the first signal wiring 961 in the second direction x.

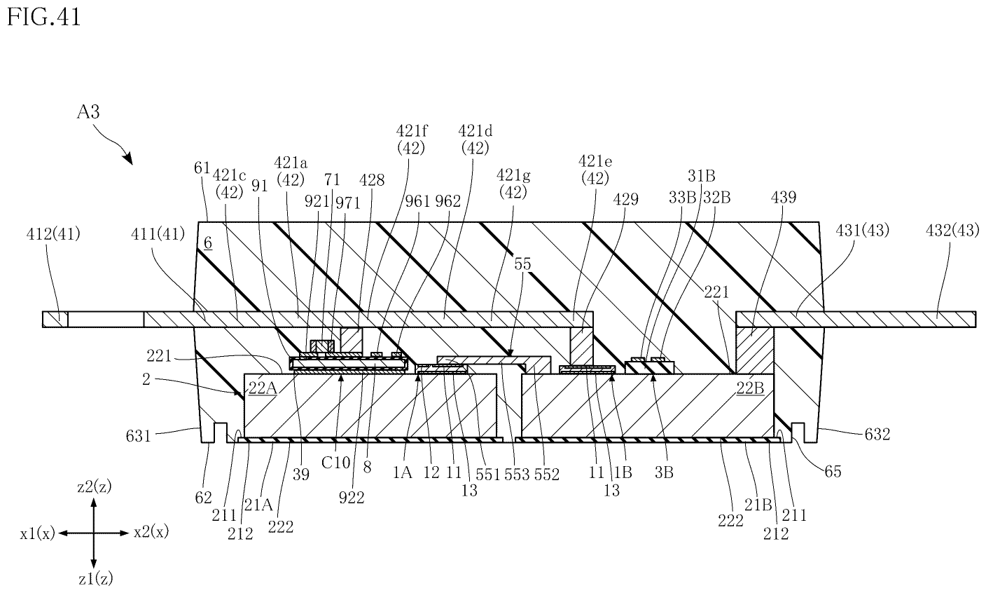

Each of the passive elements 71 is, for example, a resistor. In the example shown in FIG. 41, each passive element 71 is of a chip type. Each passive element 71 may be a capacitor or an inductor rather than a resistor. The semiconductor device A3 includes four passive elements 71 in the illustrated example, but the number of passive elements 71 is not limited to four. Each passive element 71 has a pair of electrodes, one of which is bonded to the first external electrode 921 and the other to the external wiring 971. Thus, the external wiring 971 is electrically connected to the first external electrode 921 via each passive element 71. For the convenience of understanding, the passive element 71 is shown by imaginary line in FIG. 43.

The input terminal 42 of the semiconductor device A3 differs from the input terminals 42 of the semiconductor devices A1 and A2 in the configuration of the pad portion 421. As shown in FIGS. 39 to 41, the pad portion 421 of the semiconductor device A3 includes three joining portions 421a, 421d and 421e, a plurality of strip portions 421f and 421g, and a connecting portion 421c.

The two joining portions 421d and 421e have the shape of strip extending in the third direction y as with the joining portion 421a. The three joining portions 421a, 421d and 421e are spaced apart in the second direction x and parallel (or generally parallel) to each other. In the second direction x, the joining portion 421d is located between the two joining portions 421a and 421e. The joining portion 421e overlaps with each switching element 1B in plan view.

Each of the strip portions 421f and 421g is elongated in the second direction x in plan view. As shown in FIG. 39, the strip portions 421f extend from the joining portion 421a to the joining portion 421d along the second direction x. As shown in FIG. 39, the strip portions 421g extend from the joining portion 421d to the joining portion 421e along the second direction x.

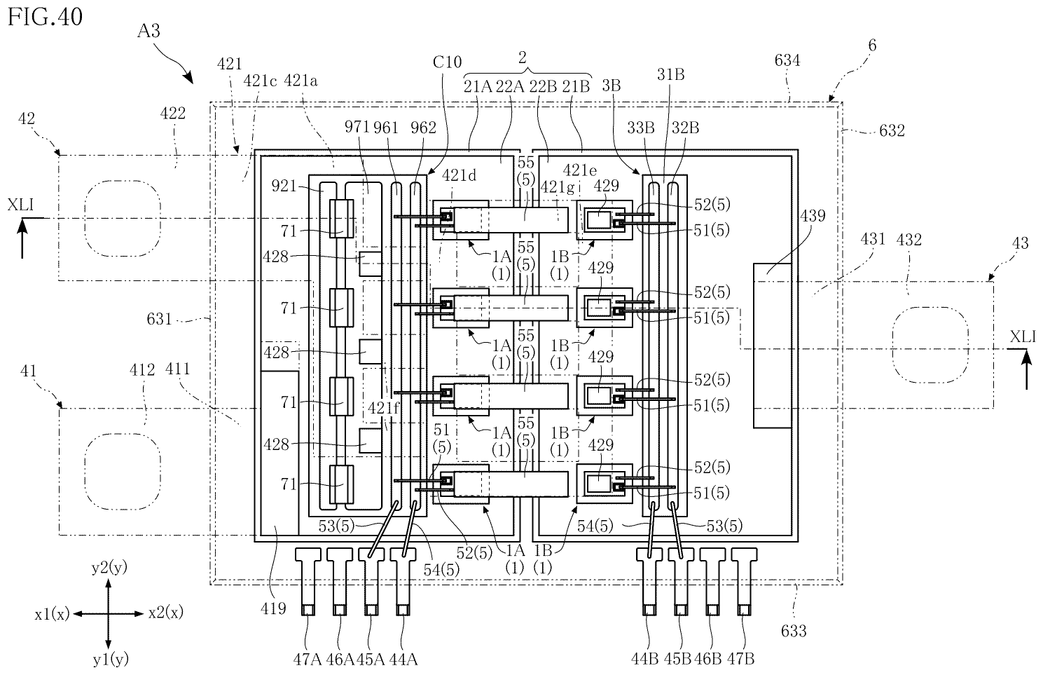

As shown in FIGS. 40 and 41, in the semiconductor device A3, the joining portion 421a and the strip portions 421f are electrically connected to the external wiring 971 of the capacitor device C10 via blocks 428. In the illustrated example, each block 428 is disposed at the boundary between the joining portion 421a and a strip portion 421f in plan view, as shown in FIG. 40. Each block 428 may entirely overlap with the joining portion 421a or may entirely overlap with a strip portion 421f in plan view. Also, in the semiconductor device A3, the joining portion 421e is electrically connected to the respective first electrodes 11 of the switching elements 1B via blocks 429 as shown in FIGS. 40 and 41.

With such a configuration, each first electrode 11 electrically conducts to the joining portion 421e via a block 428. The first electrode 11 electrically conducts to the terminal portion 422 via the connecting portion 421c through a conduction path that branches from the joining portion 421e into the strip portions 421g, then converges on the joining portion 421d, then branches from the joining portion 421d into the strip portions 421f, and then converges on the joining portion 421a. Also, the present configuration forms a current path from the second external electrode 922 of the capacitor device C10 to the first external electrode 921 of the capacitor device C10 through the conductive substrate 22A, each switching element 1A (from the third electrode 13 to the first electrode 11), each lead member 55, the conductive substrate 22B, each switching element 1B (from the third electrode 13 to the first electrode 11), each block 429, the input terminal 42 (the pad portion 421), each block 428, the external wiring 971 of the capacitor device C10, and each passive element 71 in this order.

The semiconductor device A3 can achieve the same effects as the semiconductor device A2. Moreover, in the semiconductor device A3, the capacitor element 8 of the capacitor device C10 and each passive element 71 are electrically connected in series. In the example where each passive element 71 is a resistor, the capacitance component of the capacitor element 8 and the resistance component of each passive element 71 can form an RC series circuit.

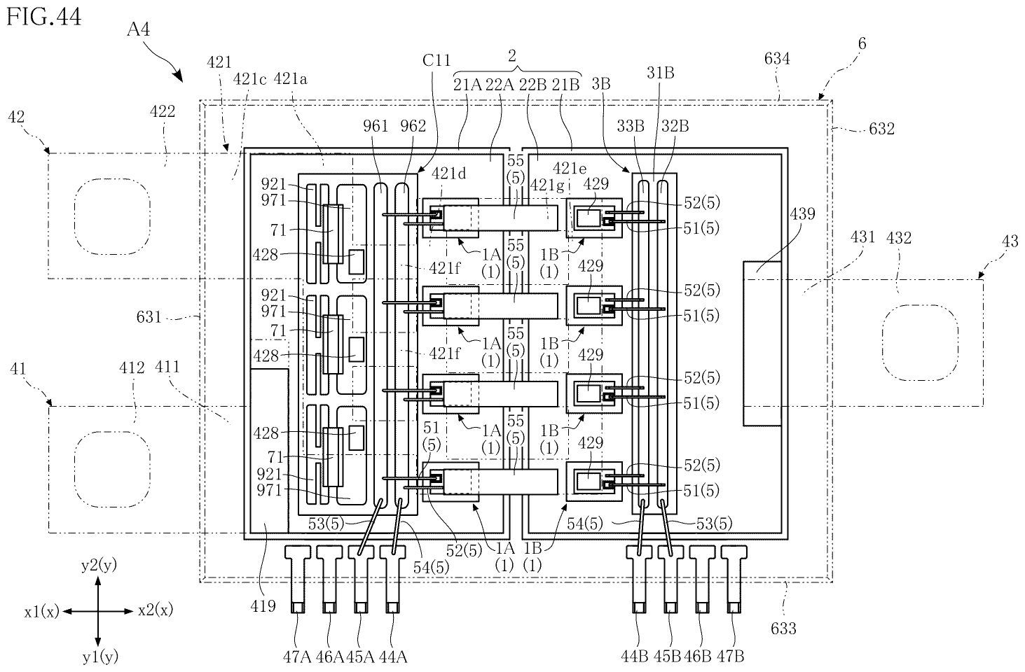

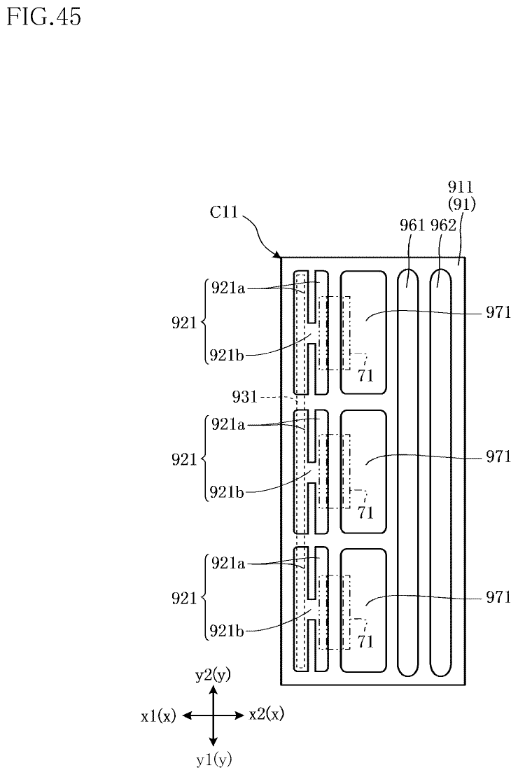

FIGS. 44 and 45 show a semiconductor device A4 according to a fourth embodiment. As shown in FIGS. 44 and 45, the semiconductor device A4 differs from the semiconductor device A3 mainly in that the semiconductor device A4 includes a capacitor device C11 instead of the capacitor device C10.

The capacitor device C11 differs from the capacitor device C10 in that the capacitor device C11 includes a plurality of first external electrodes 921. Three first external electrodes 921 are provided in the example shown in FIGS. 44 and 45, but the number of first external electrodes 921 is not limited. In the capacitor device C11, each of the first external electrodes 921 includes a portion where a conduction path is partially narrowed, as in the example shown in FIG. 25. As shown in FIG. 45, each first external electrode 921 includes a plurality of pad pattern portions 921a and a neck pattern portion 921b. Each pad pattern portion 921a is formed similarly to each pad pattern portion 831a shown in FIG. 25, and the neck pattern portion 921b is formed similarly to each neck pattern portion 831b shown in FIG. 25. In the example shown in FIG. 45, the first conductive member 931 is connected to the pad pattern portion 921a on the x1 side of each first external electrode 921.

The capacitor device C11 differs from the capacitor device C10 in that the capacitor device C11 includes a plurality of external wirings 971. In the example shown in FIGS. 44 and 45, three external wirings 971, which is the same number as the first external electrodes 921, are provided, but the number of external wirings 971 is not limited. Each of the passive elements 71 is bonded to the pad pattern portion 921a of a first external electrode 921 and an external wiring 971. In the example shown in FIGS. 44 and 45, one of the electrodes of each passive element 71 is bonded to the pad pattern portion 921a on the x2 side of a first external electrode 921. Each external wiring 971 may also include a portion where a conduction path is partially narrowed (i.e., a neck pattern portion), as with each first external electrode 921.

The semiconductor device A4 can achieve the same effects as the semiconductor device A3. Furthermore, in the semiconductor device A4, when an excessive current is generated in any of the first external electrodes 921, disconnection occurs at the neck pattern portion 921b of the first external electrode 921, thereby preventing the excessive current from flowing to other portions.

In the semiconductor devices A1 to A4, the first external electrode 921 and the second external electrode 922 of each capacitor device C1 and C9 to C11 as well as the external wiring 971 of each capacitor device C10 and C11 may include a Ni—P layer (nickel-phosphorus alloy layer) rather than copper or a copper alloy. In such a case, the resistance values of the first external electrode 921, the second external electrode 922, and the external wiring 971 increase as compared with the case where they are made of copper or copper alloy. Thus, the capacitance component of the capacitor element 8 and the respective resistance components of the first external electrode 921 and the second external electrode 922 can be used to form a CR snubber circuit. Moreover, in the above-described semiconductor devices A3 and A4, when the resistance component of each passive element 71 is insufficient, it can be compensated for by the resistance components of the first external electrode 921 and the external wiring 971. Moreover, the semiconductor device A4 can increase the amount of heat generated in each neck pattern portion 921b due to the current flowing in the first external electrode 921, so that disconnection due to the above-described excessive current can easily occur.

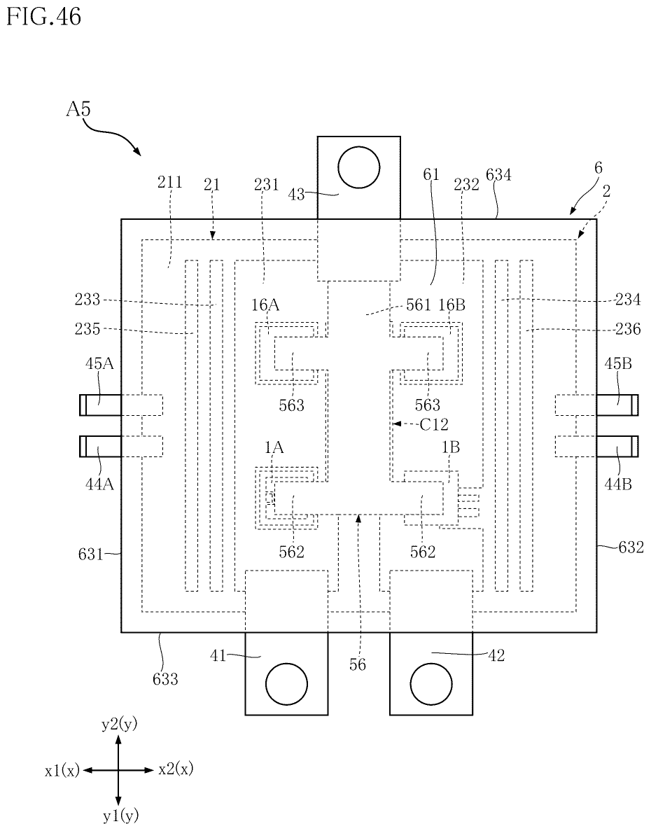

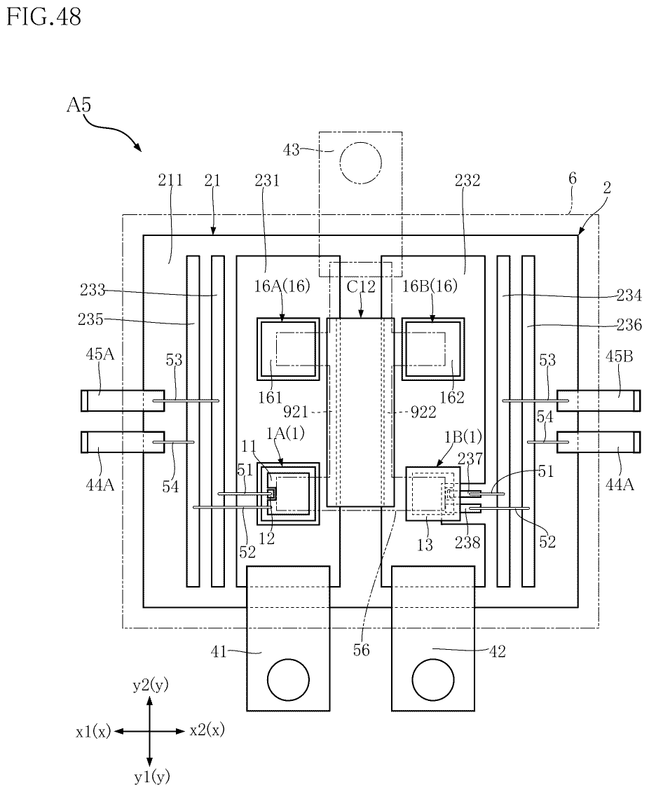

FIGS. 46 to 51 show a semiconductor device A5 according to a fifth embodiment. As shown in the figure, the semiconductor device A5 includes a pair of switching elements 1A and 1B, a pair of diodes 16A and 16B, a support substrate 2, two input terminals 41 and 42, an output terminal 43, a plurality of signal terminals 44A, 44B, 45A and 45B, plurality of gate wires 51, a plurality of detection wires 52, a plurality of first connection wires 53, a plurality of second connection wires 54, a conductive member 56, a resin member 6, a heat sink 72, and a capacitor device C12.

The support substrate 2 of the present embodiment includes an insulating substrate 21, two wiring layers 231 and 232, two gate wiring layers 233 and 234, two detection wiring layers 235 and 236, and two electrode lead-out layer 237 and 238.

As shown in FIGS. 46 to 50, the insulating substrate 21 supports the two wiring layers 231 and 232, the two gate wiring layers 233 and 234, the two detection wiring layers 235 and 236, the two electrode lead-out layers 237 and 238, and the resin member 6. The insulating substrate 21 also supports the signal terminals 44A, 44B, 45A and 45B. The insulating substrate 21 is, for example, a ceramic substrate, as with the insulating substrates 21A and 21B. The insulating substrate 21 has an obverse surface 211 and a reverse surface 212. The obverse surface 211 faces upward (the z1 side) in the first direction. The reverse surface 212 faces downward (the z2 side) in the first direction. The reverse surface 212 is exposed from the resin member 6.

The two wiring layers 231 and 232 are disposed on the obverse surface 211 of the insulating substrate 21. The constituent material of the two wiring layers 231 and 232 includes copper or a copper alloy. The switching element 1A and the diode 16A are mounted on the wiring layer 231. In the present embodiment, with the switching element 1A mounted on the wiring layer 231, the wiring layer 231 faces the element reverse surface 102 of the switching element 1A.

Although the single switching element 1A is mounted on the wiring layer 231 in the illustrated example, a plurality of switching elements 1A may be mounted. The wiring layer 231 contains copper or a copper alloy. The wiring layer 231 has a rectangular shape elongated in the third direction y in plan view. The input terminal 41 is conductively boded to the end on the y1 side in the third direction of the wiring layer 231. The switching element 1B and the diode 16B are mounted on the wiring layer 232. In the present embodiment, with the switching element 1B mounted on the wiring layer 232, the wiring layer 232 faces the element obverse surface 101 of the switching element 1B. Although the single switching element 1B is mounted on the wiring layer 232 in the illustrated example, a plurality of switching elements 1B may be mounted. The wiring layer 232 is spaced apart from the wiring layer 231 in the second direction x. The wiring layer 232 has a rectangular shape elongated in the third direction y in plan view. The wiring layer 232 is formed with a cutout in plan view. The cutout is formed on the side on which the gate wiring layer 234 and the detection wiring layer 236 are located in the second direction x. The input terminal 42 is conductively boded to the end on the y1 side in the third direction of the wiring layer 232.

The two gate wiring layers 233 and 234 are disposed on the obverse surface 211 of the insulating substrate 21. The constituent material of the two gate wiring layers 233 and 234 includes copper or a copper alloy. The gate wiring layer 233 is located on the opposite side of the wiring layer 232 with respect to the wiring layer 231 in the second direction x. A gate wire 51 is bonded to the gate wiring layer 233. The gate wiring layer 233 electrically conducts to the second electrode 12 of the switching element 1A via the gate wire 51. A first connection wire 53 is also bonded to the gate wiring layer 233. The gate wiring layer 233 electrically conducts to the signal terminal 45A via the first connection wire 53. The gate wiring layer 233 extends along the third direction y. The gate wiring layer 234 is located on the opposite side of the wiring layer 231 with respect to the wiring layer 232 in the second direction x. A gate wire 51 is bonded to the gate wiring layer 234. The gate wiring layer 234 electrically conducts to the second electrode 12 of the switching element 1B via the gate wire 51. A first connection wire 53 is also bonded to the gate wiring layer 234. The gate wiring layer 234 electrically conducts to the signal terminal 45B via the first connection wire 53. The gate wiring layer 234 extends along the third direction y.

The two detection wiring layers 235 and 236 are disposed on the obverse surface 211 of the insulating substrate 21. The constituent material of the two detection wiring layers 235 and 236 includes copper or a copper alloy. The detection wiring layer 235 is located next to the gate wiring layer 233 in the second direction x. A detection wire 52 is bonded to the detection wiring layer 235. The detection wiring layer 235 electrically conducts to the first electrode 11 of the switching element 1A via the detection wire 52. A second connection wire 54 is also bonded to the detection wiring layer 235. The detection wiring layer 235 electrically conducts to the signal terminal 44A via the second connection wire 54. The detection wiring layer 235 extends along the third direction y and is parallel to the gate wiring layer 233. The detection wiring layer 236 is located next to the gate wiring layer 234 in the second direction x. A detection wire 52 is bonded to the detection wiring layer 236. The detection wiring layer 236 electrically conducts to the first electrode 11 of the switching element 1B via the detection wire 52. A second connection wire 54 is also bonded to the detection wiring layer 236. The detection wiring layer 236 electrically conducts to the signal terminal 44B via the second connection wire 54. The detection wiring layer 236 extends along the third direction y and is parallel to the gate wiring layer 234.

The two electrode lead-out layers 237 and 238 are disposed on the obverse surface 211 of the insulating substrate 21. The constituent material of the two electrode lead-out layers 237 and 238 includes copper or a copper alloy. The two electrode lead-out layers 237 and 238 are disposed side by side in the third direction y in the cutout formed in the wiring layer 232. In plan view, the switching element 1B overlaps with the two electrode lead-out layers 237 and 238. A gate wire 51 is bonded to the electrode lead-out layer 237. The electrode lead-out layer 237 electrically conducts to the gate wiring layer 234 via the gate wire 51. The second electrode 12 of the switching element 1B is bonded to the electrode lead-out layer 237 with a conductive bonding material. With such a configuration, the second electrode 12 of the switching element 1B electrically conducts to the gate wiring layer 234 via the electrode lead-out layer 237 and the gate wire 51. A detection wire 52 is bonded to the electrode lead-out layer 238. The electrode lead-out layer 238 electrically conducts to the detection wiring layer 236 via the detection wire 52. The first electrode 11 of the switching element 1B is bonded to the electrode lead-out layer 238 with a conductive bonding material. With such a configuration, the first electrode 11 of the switching element 1B electrically conducts to the detection wiring layer 236 via the electrode lead-out layer 238 and the detection wire 52.

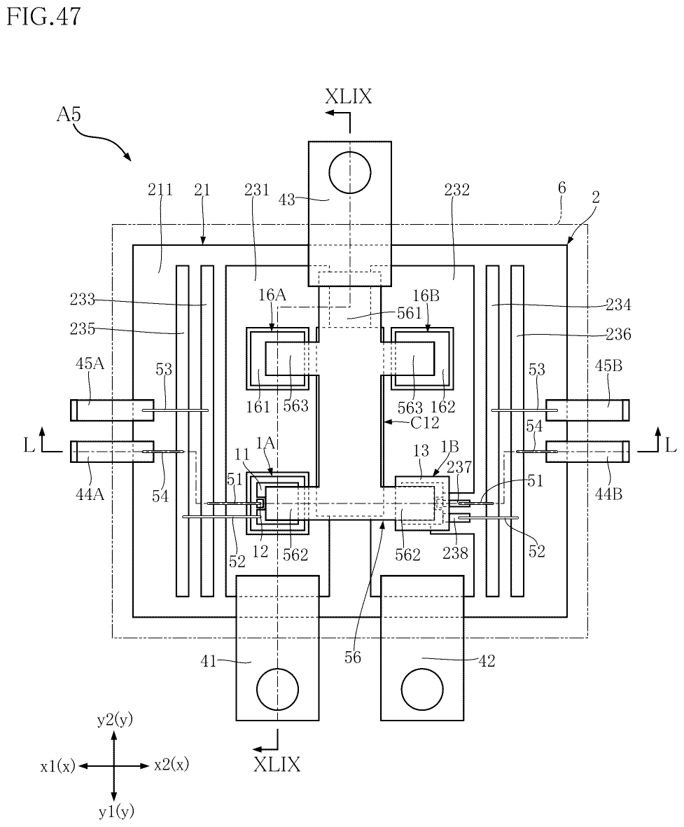

As shown in FIGS. 46 and 47, the diodes 16A and 16B are bonded to the two wiring layers 231 and 232, respectively. The diode 16A is bonded to the wiring layer 231, and the diode 16B is bonded to the wiring layer 232. Each of the pair of diodes 16A and 16B is, for example, a Schottky barrier diode. The diode 16A is connected in reverse parallel to the switching element 1A. The diode 16B is connected in reverse parallel to the switching element 1B. Each of the diodes 16A and 16B functions as a freewheeling diode.

Each of the diodes 16A and 16B has an anode electrode 161 and a cathode electrode 162. The anode electrode 161 and the cathode electrode 162 are located on opposite sides of each other in the first direction z. In the example where the switching elements 1A and 1B are MOSFETs, diodes that can replace the diodes 16A and 16B may be incorporated in the switching elements 1A and 1B. In such a case, the diodes 16A and 16B are unnecessary.

In the diode 16A, the anode electrode 161 is provided on the side in the first direction z which the obverse surface 211 of the insulating substrate 21 faces. The cathode electrode 162 of the diode 16A is disposed to face the wiring layer 231. The cathode electrode 162 of the diode 16A is bonded to the wiring layer 231 with a conductive bonding material and electrically conducts to the wiring layer 231. In the diode 16B, the cathode electrode 162 is provided on the side in the first direction z which the obverse surface 211 of the insulating substrate 21 faces. The anode electrode 161 of the diode 16B is disposed to face the wiring layer 232. The anode electrode 161 of the diode 16B is bonded to the wiring layer 232 with a conductive bonding material and electrically conducts to the wiring layer 232.

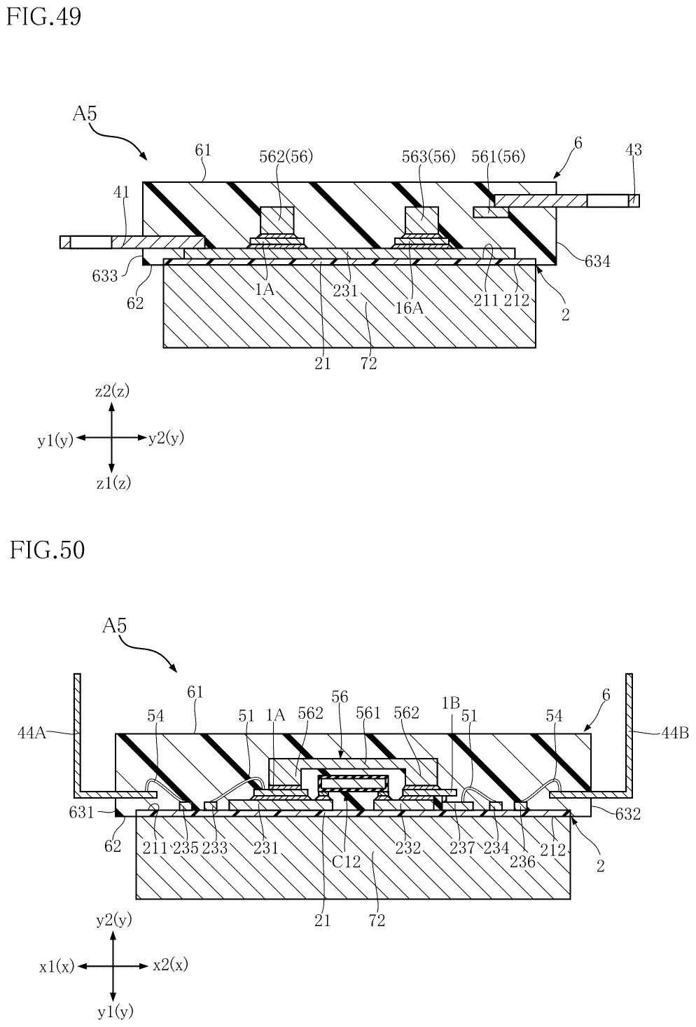

As shown in FIGS. 49 and 50, the conductive member 56 is spaced apart from the insulating substrate 21 toward the side in the first direction z which the obverse surface 211 faces. The conductive member 56 is bonded to the first electrode 11 of the switching element 1A and the third electrode 13 of the switching element 1B. The conductive member 56 is also bonded to the anode electrode 161 of the diode 16A and the cathode electrode 162 of the diode 16B. The conductive member 56 is made of a single lead frame. The constituent material of the lead frame includes, for example, copper or a copper alloy.

The conductive member 56 includes a base portion 561, a pair of first bonding portions 562, and a pair of second bonding portions 563. As shown in FIG. 47, the base portion 561 extends along the third direction y. In plan view, the base portion 561 overlaps with the two wiring layers 231 and 232 and the capacitor device C12. As shown in FIG. 49, the output terminal 43 is bonded to the end on the y2 side in the third direction of the conductive member 56.

As shown in FIGS. 47 and 50, the pair of first bonding portions 562 are connected to the opposite ends in the second direction x of the base portion 561. As understood from FIGS. 47 and 50, the pair of first bonding portions 562 are bonded to the first electrode 11 of the switching element 1A and the third electrode 13 of the switching element 1B, respectively, with a conductive bonding material. With such a configuration, the first electrode 11 of the switching element 1A and the third electrode 13 of the switching element 1B electrically conduct to the conductive member 56.

As shown in FIG. 47, the pair of second bonding portions 563 are connected to the opposite ends in the second direction x of the base portion 561. The pair of second bonding portions 563 are bonded to the anode electrode 161 of the diode 16A and the cathode electrode 162 of the diode 16B, respectively, with a conductive bonding material. With such a configuration, the anode electrode 161 of the diode 16A and the cathode electrode 162 of the diode 16B electrically conduct to the conductive member 56.

As shown in FIGS. 49 and 50, the heat sink 72 is bonded to the reverse surface 212 of the insulating substrate 21. Thus, the insulating substrate 21 is located between the heat sink 72 and the two wiring layers 231 and 232 or the conductive member 56 in the first direction z. The constituent material of the heat sink 72 includes, for example, aluminum. The semiconductor device A5 may not include the heat sink 72.

As shown in FIG. 46, in the present embodiment, the two input terminals 41 and 42 protrude from the resin side surface 633, and the output terminal 43 protrudes from the resin side surface 634. The two signal terminals 44A and 45A protrude from the resin side surface 631, and the two signal terminals 44B and 45B protrude from the resin side surface 632.

The capacitor device C12 is bonded to the two wiring layers 231 and 232. The capacitor device C12 bridges between the two wiring layers 231 and 232 in plan view. The capacitor device C12 is located between the support substrate 2 and the base portion 561 in the first direction z.

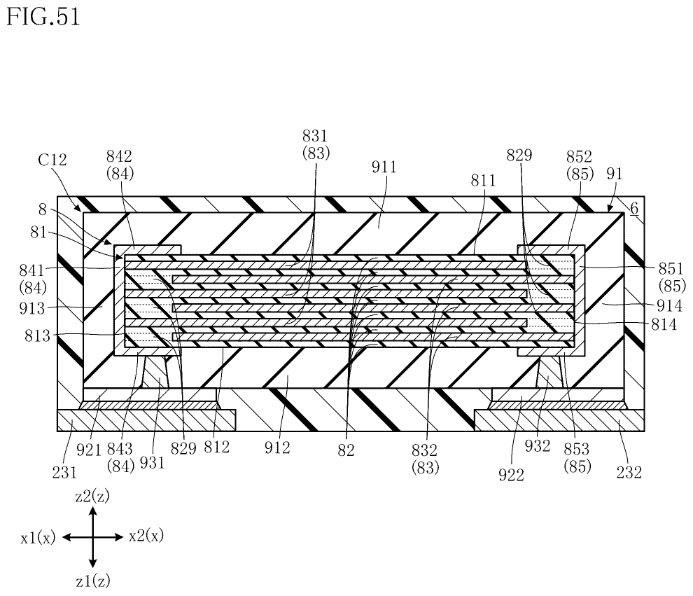

The capacitor device C12 differs from the capacitor device C1 in the following points. That is, as shown in FIG. 51, both of the first external electrode 921 and the second external electrode 922 are formed to cover the reverse covering portion 912. Because the first external electrode 921 is formed to cover the reverse covering portion 912, the first conductive member 931 penetrates the reverse covering portion 912 and is in contact with the first reverse electrode portion 843 (the first aggregate electrode 84). Each of the first external electrode 921 and the second external electrode 922 has a rectangular shape elongated in the third direction y. As shown in FIG. 51, the first external electrode 921 is disposed at the edge on the x1 side in the second direction of the insulating cover 91, and the second external electrode 922 is disposed at the edge on the x2 side in the second direction of the insulating cover 91. The first external electrode 921 is bonded to the wiring layer 231 via a conductive bonding material, and the second external electrode 922 is bonded to the wiring layer 232 via a conductive bonding material.

In the semiconductor device A5, the first external electrode 921 of the capacitor device C12 is bonded to the wiring layer 231 on which the switching element 1A is mounted, and the second external electrode 922 of the capacitor device C12 is mounted to the wiring layer 232 on which the switching element 1B is mounted. Such a configuration forms a current path from the capacitor device C12 (the first external electrode 921) to the capacitor device C12 (the second external electrode 922) through the wiring layer 231, the switching element 1A (from the third electrode 13 to the first electrode 11), the conductive member 56, the switching element 1B (from the third electrode 13 to the first electrode 11), and the wiring layer 232 in this order. As with the semiconductor device A1, the semiconductor device A5 reduces the internal inductance by forming such a current path.

In the semiconductor device A5, each of the first external electrode 921 and the second external electrode 922 of the capacitor device C12 is formed to cover the reverse covering portion 912. That is, the first external electrode 921 and the second external electrode 922 are formed on the lower side of the capacitor device C12, and no external electrodes (the first external electrode 921 and the second external electrode 922) are located on the upper side of the capacitor device C12. With such a configuration, unintended contact (short circuit) between the conductive member 56 and the capacitor device C12 can be prevented when the conductive member 56 is disposed above the capacitor device C12.

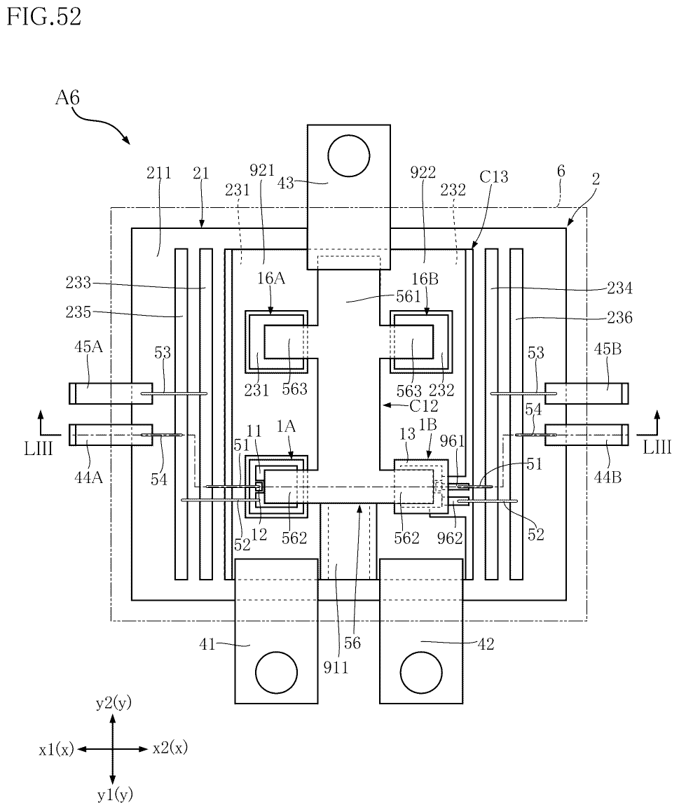

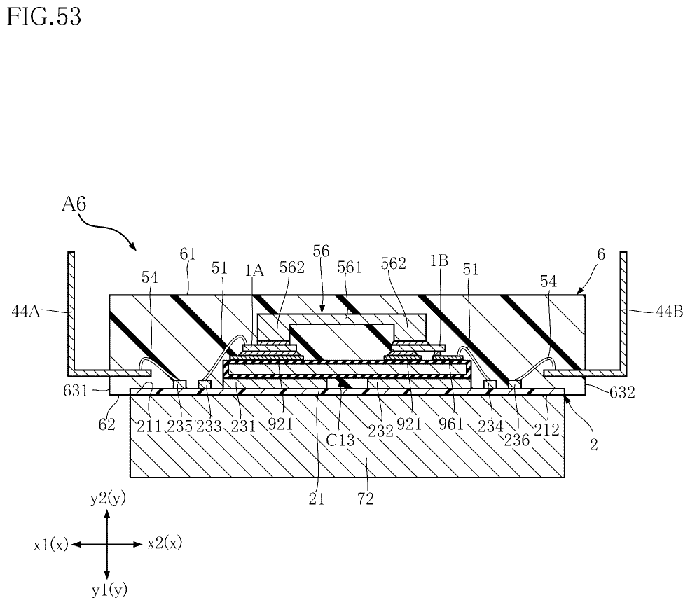

FIGS. 52 to 54 show a semiconductor device A6 according to a sixth embodiment. As shown in the figures, the semiconductor device A6 differs from the semiconductor device A5 in the following points. First, the semiconductor device A6 includes a capacitor device C13 instead of the capacitor device C12. Second, the two switching elements 1A and 1B and the two diodes 16A and 16B are mounted on the capacitor device C13.

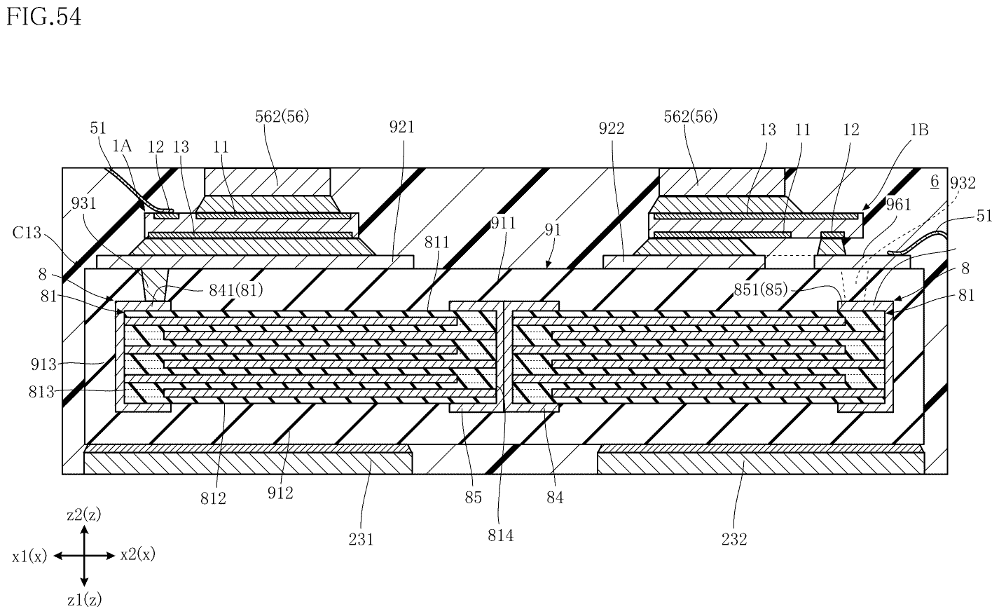

The capacitor device C13 differs from the capacitor device C5 in the following points. That is, as shown in FIG. 54, both the first external electrode 921 and the second external electrode 922 are formed to cover the obverse covering portion 911. Because the second external electrode 922 is formed to cover the obverse covering portion 911, the second conductive member 932 penetrates the obverse covering portion 911 and is in contact with the second side electrode portion 851 (the second aggregate electrode 85). As shown in FIG. 54, the first external electrode 921 is disposed along the edge on the x1 side in the second direction of the insulating cover 91, and the second external electrode 922 is disposed along the edge on the x2 side in the second direction of the insulating cover 91. The third electrode 13 of the switching element 1A and the cathode electrode 162 of the diode 16A are bonded to the first external electrode 921 with a conductive bonding material. The first electrode 11 of the switching element 1B and the anode electrode 161 of the diode 16B are bonded to the second external electrode 922 with a conductive bonding material. The second external electrode 922 is formed with a cutout in plan view. The cutout is formed on the side on which the gate wiring layer 234 and the detection wiring layer 236 are located in the second direction x.

The capacitor device C13 includes the first signal wiring 961 and the second signal wiring 962. As shown in FIG. 52, each of the first signal wiring 961 and the second signal wiring 962 of the present embodiment has the shape of a strip extending in the second direction x. The first signal wiring 961 and the second signal wiring 962 are disposed side by side in the third direction y and parallel to the second direction x. The first signal wiring 961 and the second signal wiring 962 are located in the cutout formed in the second external electrode 922. A gate wire 51 is bonded to the first signal wiring 961. The first signal wiring 961 electrically conducts to the gate wiring layer 234 via the gate wire 51. Also, the second electrode 12 of the switching element 1B is bonded to the first signal wiring 961 with a conductive bonding material. With such a configuration, the second electrode 12 of the switching element 1B electrically conducts to the gate wiring layer 234 via the first signal wiring 961 and the gate wire 51. A detection wire 52 is bonded to the second signal wiring 962. The second signal wiring 962 electrically conducts to the detection wiring layer 236 via the detection wire 52. Also, the first electrode 11 of the switching element 1B is bonded to the second signal wiring 962 with a conductive bonding material. With such a configuration, the first electrode 11 of the switching element 1B electrically conducts to the detection wiring layer 236 via the second signal wiring 962 and the detection wire 52.

In the semiconductor device A6, the wiring layer 232 may not be formed with the cutout, and the support substrate 2 may not include either of the two electrode lead-out layers 237 and 238. In the semiconductor device A6, the capacitor device C13 is disposed on the two wiring layers 231 and 232, but does not electrically conduct to these wiring layers. The capacitor device C13 includes two capacitor elements 8 in the illustrated example. However, the number of capacitor elements 8 of the capacitor device C13 is not limited and may be one or three or more.

In the semiconductor device A6, the switching element 1A is mounted on the first external electrode 921 of the capacitor device C13, and the switching element 1B is mounted on the second external electrode 922 of the capacitor device C13. Such a configuration forms a current path from the capacitor device C13 (the first external electrode 921) to the capacitor device C13 (the second external electrode 922) through the switching element 1A (from the third electrode 13 to the first electrode 11), the conductive member 56, and the switching element 1B in this order. As with the semiconductor device A1, the semiconductor device A6 reduces the internal inductance by forming such a current path.

In the semiconductor device A6, the two switching elements 1A and 1B and the two diodes 16A and 16B are mounted on the capacitor device C13. With such a configuration, the capacitor device C13 can be made larger as compared with that in the semiconductor device A5, whereby the capacitance of the capacitor device C13 can be made higher. That is, the semiconductor device A6 has a configuration that is preferred when a capacitor device C13 with high capacitance is needed (for example, the supply voltage inputted to the two input terminals 41 and 42 is high).

The capacitor device and the semiconductor device according to the present disclosure are not limited to the above-described embodiments. Various modifications in design may be made freely in the specific structure of each part of the capacitor device and the semiconductor device according to the present disclosure. The present disclosure includes embodiments described in the following clauses.

### Clause 1.

A capacitor device comprising:
a capacitor element;
an insulating cover covering the capacitor element;
a first external electrode exposed from the insulating cover;
a second external electrode exposed from the insulating cover;
a first conductive member electrically conducting to the first external electrode and the capacitor element; and
a second conductive member electrically conducting to the second external electrode and the capacitor element, wherein
the capacitor element includes a multilayer body comprising a plurality of dielectric layers and a plurality of conductor layers alternately laminated in a first direction,
the insulating cover covers an entirety of the capacitor element except a connection portion where the capacitor element and the first conductive member are connected and a connection portion where the capacitor element and the second conductive member are connected, and
the first external electrode and the second external electrode are formed on opposite sides of each other in the first direction.

### Clause 2.

The capacitor device according to clause 1, wherein the capacitor element includes a first aggregate electrode to which the first conductive member is connected and a second aggregate electrode to which the second conductive member is connected, and
the plurality of conductor layers include a plurality of first electrode layers connected to the first aggregate electrode and a plurality of second electrode layers connected to the second aggregate electrode.

### Clause 3.

The capacitor device according to clause 2, wherein the multilayer body includes an obverse surface and a reverse surface spaced apart in the first direction,
the insulating cover includes an obverse covering portion covering the obverse surface and a reverse covering portion covering the reverse surface,
the first external electrode covers a part of the obverse covering portion, and
the second external electrode covers a part of the reverse covering portion.

### Clause 4.

The capacitor device according to clause 3, wherein the multilayer body includes a first side surface and a second side surface spaced apart in a second direction orthogonal to the first direction,
each of the first side surface and the second side surface is connected to the obverse surface and the reverse surface,
the first aggregate electrode includes a first side electrode portion covering the first side surface, and
the second aggregate electrode includes a second side electrode portion covering the second side surface.

### Clause 5.

The capacitor device according to clause 4, wherein the first aggregate electrode includes a first obverse electrode portion covering a part of the obverse surface and a first reverse electrode portion covering a part of the reverse surface,
the first obverse electrode portion and the first reverse electrode portion are connected to the first side electrode portion,
the second aggregate electrode includes a second obverse electrode portion covering a part of the reverse surface and a second reverse electrode portion covering a part of the reverse surface, and
the second obverse electrode portion and the second reverse electrode portion are connected to the second side electrode portion.

### Clause 6.

The capacitor device according to clause 5, wherein the first conductive member penetrates the insulating cover in the first direction, and
the second conductive member penetrates the insulating cover in the first direction.

### Clause 7.

The capacitor device according to clause 6, wherein the first conductive member is in contact with the first obverse electrode portion, and
the second conductive member is in contact with the second reverse electrode portion.

### Clause 8.

The capacitor device according to clause 6, wherein the first conductive member is in contact with the first side electrode portion, and
the second conductive member is in contact with the second side electrode portion.

### Clause 9.

The capacitor device according to any one of clauses 3 to 8, further comprising:
one or more first vias that penetrate the obverse covering portion in the first direction and are in contact with the obverse surface; and
one or more second vias that penetrate the reverse covering portion in the first direction and are in contact with the reverse surface.

### Clause 10.

The capacitor device according to clause 9, wherein the one or more first vias are connected to the first external electrode, and
the one or more second vias are connected to the second external electrode.

### Clause 11.

The capacitor device according to any one of clauses 1 to 10, wherein the capacitor element is a first capacitor element, and the capacitor device further comprises a second capacitor element.

### Clause 12.

The capacitor device according to clause 11, wherein the first capacitor element and the second capacitor element are electrically connected in parallel.

### Clause 13.

The capacitor device according to clause 11, wherein the first capacitor element and the second capacitor element are electrically connected in series.

### Clause 14.

The capacitor device according to any one of clauses 1 to 13, wherein a constituent material of the insulating cover and a constituent material of the dielectric layers are different.

### Clause 15.

The capacitor device according to any one of clauses 1 to 14, wherein the first external electrode and the second external electrode include a Ni—P layer.

### Clause 16.

The capacitor device according to any one of clauses 1 to 15, wherein at least one of the plurality of conductor layers, the first external electrode or the second external electrode includes a neck pattern portion where a conduction path is partially narrowed.

### Clause 17.

A semiconductor device comprising:
the capacitor device as set forth in any one of clauses 1 to 16; and
a first switching element and a second switching element connected in series to form a bridge,
wherein the first external electrode and the second external electrode are electrically connected to opposite ends of the bridge.

### Clause 18.

The semiconductor device according to clause 17, further comprising:
a first mount portion on which the first switching element is mounted; and
a second mount portion on which the second switching element is mounted, wherein
the first mount portion and the second mount portion are spaced apart from each other, and
the first mount portion faces at least a part of the capacitor device in the first direction.

### Clause 19.

The semiconductor device according to clause 17 or 18, wherein the first switching element and the second switching element comprises SiC.

### Clause 20.

The semiconductor device according to any one of clauses 17 to 19, further comprising a passive element electrically connected in series to the capacitor device.

### REFERENCE NUMERALS

A1, A2, A3, A4: Semiconductor device
C1 to C11: Capacitor device
1, 1A, 1B: Switching element
101: Element obverse surface 102: Element reverse surface
11: First electrode 12: Second electrode
13: Third electrode 14: Insulating film
16A, 16B: Diode 161: Anode electrode
162: Cathode electrode 2: Support substrate
21, 21A, 21B: Insulating substrate 211: Obverse surface
212: Reverse surface 22A, 22B: Conductive substrate
221: Obverse surface 222: Reverse surface
231, 232: Wiring layer 233, 234: Gate wiring layer
235, 236: Detection wiring layer
237, 238: Electrode lead-out layer
3A, 3B: Signal substrate 31A, 31B: Insulating layer
32A, 32B: Gate layer 33A, 33B: Detection layer
41: Input terminal 411: Pad portion
412: Terminal portion 419: Block
42: Input terminal 421: Pad portion
421a, 421d, 421e: Joining portion 421b: Extending portion
421c: Connecting portion 421f, 421g: Strip portion
422: Terminal portion 428, 429: Block
43: Output terminal 431: Pad portion
432: Terminal portion 439: Block
44A to 47A, 44B to 47B: Signal terminal
441, 451, 461, 471: Pad portion
442, 452, 462, 472: Terminal portion 5: Connecting member
51: Gate wire 52: Detection wire
53: First connection wire 54: Second connection wire
55: Lead member 551: First bonding portion
552: Second bonding portion 553: Link portion
56: Conductive member 561: Base portion
562: First bonding portion 563: Second bonding portion
6: Resin member 61: Resin obverse surface
62: Resin reverse surface 631 to 634: Resin side surface
65: Recess 71: Passive element
72: Heat sink 8: Capacitor element
81: Multilayer body 82: Dielectric layer
83: Conductor layer 84: First aggregate electrode
85: Second aggregate electrode 811: Obverse surface
812: Reverse surface 813: First side surface
814: Second side surface 815: Third side surface
816: Fourth side surface 829: Insulator
831: First electrode layer 831a: Pad pattern portion
831b: Neck pattern portion 832: Second electrode layer
841: First side electrode portion
842: First obverse electrode portion
843: First reverse electrode portion
851: Second side electrode portion
852: Second obverse electrode portion
853: Second reverse electrode portion
91: Insulating cover 911: Obverse covering portion
912: Reverse covering portion
913: First side covering portion
914: Second side covering portion
915: Third side covering portion
916: Fourth side covering portion
921: First external electrode
921a: Pad pattern portion 921b: Neck pattern portion
922: Second external electrode 931: First conductive member
932: Second conductive member 933: Third conductive member
934: Fourth conductive member 941: First wiring electrode
942: Second wiring electrode 951: First via
952: Second via 961: First signal wiring
962: Second signal wiring 971: External wiring

1. A capacitor device comprising:
a capacitor element;
an insulating cover covering the capacitor element;
a first external electrode exposed from the insulating cover;
a second external electrode exposed from the insulating cover;
a first conductive member electrically conducting to the first external electrode and the capacitor element; and
a second conductive member electrically conducting to the second external electrode and the capacitor element, wherein
the capacitor element includes a multilayer body comprising a plurality of dielectric layers and a plurality of conductor layers alternately laminated in a first direction,
the insulating cover covers an entirety of the capacitor element except a connection portion where the capacitor element and the first conductive member are connected and a connection portion where the capacitor element and the second conductive member are connected, and
the first external electrode and the second external electrode are formed on opposite sides of each other in the first direction.

2. The capacitor device according to claim 1, wherein the capacitor element includes a first aggregate electrode to which the first conductive member is connected and a second aggregate electrode to which the second conductive member is connected, and
the plurality of conductor layers include a plurality of first electrode layers connected to the first aggregate electrode and a plurality of second electrode layers connected to the second aggregate electrode.

3. The capacitor device according to claim 2, wherein the multilayer body includes an obverse surface and a reverse surface spaced apart in the first direction,
the insulating cover includes an obverse covering portion covering the obverse surface and a reverse covering portion covering the reverse surface,
the first external electrode covers a part of the obverse covering portion, and
the second external electrode covers a part of the reverse covering portion.

4. The capacitor device according to claim 3, wherein the multilayer body includes a first side surface and a second side surface spaced apart in a second direction orthogonal to the first direction,
each of the first side surface and the second side surface is connected to the obverse surface and the reverse surface,
the first aggregate electrode includes a first side electrode portion covering the first side surface, and
the second aggregate electrode includes a second side electrode portion covering the second side surface.

5. The capacitor device according to claim 4, wherein the first aggregate electrode includes a first obverse electrode portion covering a part of the obverse surface and a first reverse electrode portion covering a part of the reverse surface,
the first obverse electrode portion and the first reverse electrode portion are connected to the first side electrode portion,
the second aggregate electrode includes a second obverse electrode portion covering a part of the reverse surface and a second reverse electrode portion covering a part of the reverse surface, and
the second obverse electrode portion and the second reverse electrode portion are connected to the second side electrode portion.

6. The capacitor device according to claim 5, wherein the first conductive member penetrates the insulating cover in the first direction, and
the second conductive member penetrates the insulating cover in the first direction.

7. The capacitor device according to claim 6, wherein the first conductive member is in contact with the first obverse electrode portion, and
the second conductive member is in contact with the second reverse electrode portion.

8. The capacitor device according to claim 6, wherein the first conductive member is in contact with the first side electrode portion, and
the second conductive member is in contact with the second side electrode portion.

9. The capacitor device according to claim 3, further comprising:
one or more first vias that penetrate the obverse covering portion in the first direction and are in contact with the obverse surface; and
one or more second vias that penetrate the reverse covering portion in the first direction and are in contact with the reverse surface.

10. The capacitor device according to claim 9, wherein the one or more first vias are connected to the first external electrode, and
the one or more second vias are connected to the second external electrode.

11. The capacitor device according to claim 1, wherein the capacitor element is a first capacitor element, and the capacitor device further comprises a second capacitor element.

12. The capacitor device according to claim 11, wherein the first capacitor element and the second capacitor element are electrically connected in parallel.

13. The capacitor device according to claim 11, wherein the first capacitor element and the second capacitor element are electrically connected in series.

14. The capacitor device according to claim 1, wherein a constituent material of the insulating cover and a constituent material of the dielectric layers are different.

15. The capacitor device according to claim 1, wherein the first external electrode and the second external electrode include a Ni—P layer.

16. The capacitor device according to claim 1, wherein at least one of the plurality of conductor layers, the first external electrode or the second external electrode includes a neck pattern portion where a conduction path is partially narrowed.

17. A semiconductor device comprising:
the capacitor device as set forth in claim 1; and
a first switching element and a second switching element connected in series to form a bridge,
wherein the first external electrode and the second external electrode are electrically connected to opposite ends of the bridge.

18. The semiconductor device according to claim 17, further comprising:
a first mount portion on which the first switching element is mounted; and
a second mount portion on which the second switching element is mounted, wherein
the first mount portion and the second mount portion are spaced apart from each other, and
the first mount portion faces at least a part of the capacitor device in the first direction.

19. The semiconductor device according to claim 17, wherein the first switching element and the second switching element comprises SiC.

20. The semiconductor device according to claim 17, further comprising a passive element electrically connected in series to the capacitor device.
